(19) United States
(12) Patent Application Publication
(10) Pub. No.: US 2025/0244807 A1
(43) Pub. Date: Jul. 31, 2025

(54) SYSTEMS AND METHODS FOR TEMPERATURE REGULATION OF ELECTRONIC DEVICES

(71) Applicant: NVIDIA CORPORATION, Santa Clara, CA (US)

(72) Inventors: John FRANZ, Tomball, TX (US); Tahir CADER, Spokane Valley, WA (US); Mohammed Amin GODIL, Vancouver, WA (US)

(73) Assignee: NVIDIA CORPORATION, Santa Clara, CA (US)

(21) Appl. No.: 19/019,738

(22) Filed: Jan. 14, 2025

Related U.S. Application Data
(60) Provisional application No. 63/625,004, filed on Jan. 25, 2024.

(51) Int. Cl. G06F 1/20; H05K 7/20

(52) U.S. Cl. CPC G06F 1/206; H05K 7/20254; H05K 7/20272; H05K 7/20281

(57) ABSTRACT

Systems and methods are provided for temperature regulation of electronic devices. An example system may include a distribution manifold including entrance flow passages and exit flow passages. Further, the system may include a heat transfer plate including heat transfer surfaces defining a plurality of gaps therebetween. The entrance flow passages may deliver heat transfer fluid to the plurality of gaps, and the exit flow passages may receive the heat transfer fluid from the plurality of gaps.

### CROSS REFERENCE TO RELATED APPLICATIONS

This application is a non-provisional application of and claims priority to U.S. Provisional Application No. 63/625,004, filed Jan. 25, 2024, the contents of which are also incorporated herein by reference.

### TECHNOLOGICAL FIELD

Example embodiments of the present disclosure generally relate to regulating temperatures of electronic devices.

### BACKGROUND

Electronic devices, such as graphics processing units (GPUs), central processing units (CPUs), and data processing units (DPUs), can generate heat during operation. In order to preserve optimal function and maximum life, overheating of such devices must be avoided. Further, in some cases, electronic devices may need to be heated to an optimal operating temperature. Applicant has identified numerous deficiencies and problems associated with conventional processes for regulating the temperature of electronic devices. Through applied effort, ingenuity, and innovation, many of these identified problems have been solved by developing solutions that are included in embodiments of the present disclosure, many examples of which are described in detail herein.

### GENERAL DESCRIPTION

Embodiments of the present disclosure are directed to regulating the temperature of electronic devices. A need exists to regulate the temperature of electronic devices efficiently and effectively due to the thermal sensitivity of the electronic devices and associated components. As such, embodiments of the disclosure described herein may include promoting even temperature regulation of a component (e.g., an electronic device) by lowering the temperature of a component (e.g., cooling), raising the temperature of a component (e.g., heating), or otherwise maintaining an optimal temperature of a component.

In one embodiment, a system for regulating temperature of an electronic device is provided. In some embodiments, the system may include a distribution manifold. In some embodiments, the distribution manifold may include a plurality of entrance flow passages configured to receive a heat transfer fluid therethrough. In some embodiments, the distribution manifold may include a plurality of exit flow passages configured to receive the heat transfer fluid therethrough. In some embodiments, the distribution manifold may include a heat transfer plate including a plurality of heat transfer surfaces proximate the distribution manifold. In some embodiments, the plurality of heat transfer surfaces may extend from the heat transfer plate toward the distribution manifold. In some embodiments, the heat transfer fins may define a plurality of gaps therebetween. In some embodiments, the plurality of entrance flow passages may be configured to deliver the heat transfer fluid to the plurality of gaps. In some embodiments, the plurality of exit flow passages may be configured to receive the heat transfer fluid from the plurality of gaps.

In some embodiments, the system may include a gasket configured to be disposed proximate the distribution manifold.

In some embodiments, the gasket may be configured to form a seal between the entrance flow passages and the exit flow passages to prevent a bypass of the heat transfer fluid. In some embodiments, the gasket may be configured to control an inflow of the heat transfer fluid to the entrance flow passages. In some embodiments, the gasket may be configured to control an outflow of the heat transfer fluid from the exit flow passages.

In some embodiments, the gasket may define an entrance aperture, wherein the entrance aperture is configured to distribute the heat transfer fluid to the entrance flow passages. In some embodiments, the gasket may define an exit aperture, wherein the exit aperture is configured to receive the heat transfer fluid from the exit flow passages.

In some embodiments, the gasket may define at least two exit apertures, wherein each exit aperture is configured to be aligned with an end of a respective exit flow passage.

In some embodiments, the gasket may be configured to distribute the heat transfer fluid to the plurality of gaps. In some embodiments, the gasket may be configured to receive the heat transfer fluid from the plurality of gaps.

In some embodiments, the gasket may be configured to form a seal between each of the plurality of heat transfer surfaces to prevent a bypass of the heat transfer fluid. In some embodiments, the gasket may be configured to control an inflow of the heat transfer fluid to the plurality of gaps. In some embodiments, the gasket may be configured to control an outflow of the heat transfer fluid from the plurality of gaps.

In some embodiments, the system may include a coupler in fluid communication with the plurality of entrance flow passages, wherein the coupler is configured to receive the heat transfer fluid from a source of heat transfer fluid, and wherein the coupler is configured to deliver the heat transfer fluid to the plurality of entrance flow passages.

In some embodiments, the system may include a top cover configured to be disposed proximate a gasket. In some embodiments, the system may include a coupler in fluid communication with the top cover and configured to receive the heat transfer fluid from a source of heat transfer fluid, wherein the coupler is configured to deliver the heat transfer fluid to the top cover. In some embodiments,

the top cover may define an entrance opening, wherein the entrance opening may be configured to promote even distribution of the heat transfer fluid to an entrance aperture of the gasket. In some embodiments, the top cover may further define an exit opening, wherein the exit opening is configured to receive the heat transfer fluid from an exit aperture of the gasket.

In some embodiments, the coupler may be further configured to receive the heat transfer fluid from the plurality of exit flow passages.

In some embodiments, the system may be configured to promote temperature regulation of a component including at least one of a graphics processing unit, a data processing unit, a central processing unit, or an electronic device.

In another embodiment, a distribution manifold is provided. In some embodiments, the distribution manifold may include a plurality of entrance flow passages configured to receive a heat transfer fluid therethrough. In some embodiments, the distribution manifold may include a plurality of exit flow passages configured to receive the heat transfer fluid therethrough. In some embodiments, the distribution manifold may be configured to be disposed proximate a heat transfer plate comprising a plurality of heat transfer surfaces, wherein the plurality of heat transfer surfaces extends from the heat transfer plate toward the distribution manifold, and wherein the plurality of heat transfer surfaces defines a plurality of gaps therebetween. In some embodiments, the plurality of entrance flow passages may be configured to deliver the heat transfer fluid to the plurality of gaps. In some embodiments, the plurality of exit flow passages may be configured to receive the heat transfer fluid from the plurality of gaps.

In some embodiments, the distribution manifold may define a first end and a second end, wherein at least one of the plurality of entrance flow passages is narrower proximate the first end and is wider proximate the second end.

In some embodiments, the distribution manifold may define defines a first end and a second end, wherein at least one of the plurality of exit flow passages is wider proximate the first end and is narrower proximate the second end.

In some embodiments, each of the plurality of entrance flow passages and each of the plurality of exit flow passages may include at least one vertical flow channel, and wherein the plurality of entrance flow passages and the plurality of exit flow passages are in fluid communication with the plurality of gaps via the vertical flow channels.

In some embodiments, at least one of the vertical flow channels may define a variable nominal width.

In some embodiments, a nominal width of at least one of the vertical flow channels may be determined based on an expected thermal performance of a component to be temperature-regulated proximate the at least one vertical flow channel.

In some embodiments, at least one of the vertical flow channels may further include a taper, wherein a direction of the taper corresponds to a direction of flow of the heat transfer fluid through the respective vertical flow channel.

In some embodiments, each of the plurality of entrance flow passages and each of the plurality of exit flow passages may define a passage length, wherein a length of at least one of the vertical flow channels is substantially the same as the slot length.

In some embodiments, the distribution manifold may define a transverse direction, wherein the plurality of entrance flow passages and the plurality of exit flow passages are aligned with the transverse direction. In some embodiments, the distribution manifold may define a longitudinal direction, wherein the gaps defined by the plurality of heat transfer surfaces are aligned with the longitudinal direction.

In some embodiments, each of the plurality of entrance flow passages may be substantially parallel to an adjacent exit flow passage.

### BRIEF DESCRIPTION OF THE DRAWINGS

Having described certain example embodiments of the present disclosure in general terms above, reference now will be made to the accompanying drawings, which may not be drawn to scale. The components illustrated in the figures may or may not be present in certain embodiments described herein. Some embodiments may include fewer (or more) components than those shown in the figures.

FIG. 1 illustrates a perspective view of a distribution manifold, in accordance with some embodiments described herein;

FIG. 2 illustrates a front view of a system for regulating temperature, in accordance with some embodiments described herein;

FIG. 3 illustrates a back view of the system of FIG. 2, in accordance with some embodiments described herein;

FIG. 4A illustrates an exploded view of the system of FIG. 2, in accordance with some embodiments described herein;

FIG. 4B illustrates an exploded view of a system wherein a gasket is disposed proximate the distribution manifold and proximate a heat transfer plate, in accordance with some embodiments described herein;

FIG. 5 illustrates a detail view of entrance flow slots and exit flow slots of the distribution manifold of FIG. 1, in accordance with some embodiments described herein;

FIG. 6 illustrates a detail perspective section view of the entrance and exit flow slots of the distribution manifold of FIG. 1 coupled to a heat transfer plate, in accordance with some embodiments described herein;

FIG. 7 illustrates a detail view of the orientation direction of surfaces associated with the heat transfer plate, in accordance with some embodiments described herein;

FIG. 8 illustrates a detail perspective view of the surfaces of the heat transfer plate, in accordance with some embodiments described herein;

FIG. 9 illustrates a section view of the distribution manifold of FIG. 1 coupled to the heat transfer plate, in accordance with some embodiments described herein;

FIG. 10 illustrates a bottom perspective view of a gasket coupled to a top cover of the system of FIG. 4A, in accordance with some embodiments described herein;

FIG. 11 illustrates a top view of the gasket of FIG. 10 coupled to the distribution manifold, in accordance with some embodiments described herein;

FIG. 12 illustrates a perspective view another system, in accordance with some embodiments described herein;

FIG. 13 illustrates an exploded view of the system of FIG. 12, in accordance with some embodiments described herein;

FIG. 14 illustrates a top view of a distribution manifold of the system of FIG. 12, in accordance with some embodiments described herein;

FIG. 15 illustrates a detail section view of vertical flow channels of the distribution manifold of FIG. 14, in accordance with some embodiments described herein;

FIG. 16 illustrates a top view of a gasket coupled to the distribution manifold of FIG. 12, in accordance with some embodiments described herein;

FIG. 17 illustrates a top view of a top cover coupled to the distribution manifold of FIG. 12, in accordance with some embodiments described herein;

FIG. 18 illustrates a top view of the top cover of FIG. 17 showing a fluid director, in accordance with some embodiments described herein;

FIG. 19 illustrates a close-up bottom perspective view of the top cover of FIG. 17, in accordance with some embodiments described herein;

FIG. 20 illustrates a process flow for manufacturing the distribution manifold, in accordance with some embodiments described herein;

FIG. 21 illustrates a network configuration used to perform one or more operations, in accordance with some embodiments described herein;

FIG. 22 illustrates an exemplary datacenter wherein a system for temperature regulation is installed, in accordance with some embodiments described herein;

FIG. 23 illustrates a computer system 1100 configured to implement various processes and methods described throughout this disclosure, in accordance with some embodiments described herein; and

FIG. 24 illustrates a block diagram that schematically illustrates a computing system 1000 comprising a plurality of subsystems, in accordance with some embodiments described herein.

### DETAILED DESCRIPTION

Embodiments of the present disclosure now will be described more fully hereinafter with reference to the accompanying drawings in which some but not all embodiments are shown. Indeed, the present disclosure may be embodied in many different forms and should not be construed as limited to the embodiments set forth herein; rather, these embodiments are provided so that this disclosure will satisfy applicable legal requirements. Like numbers refer to like elements throughout. As used herein, terms such as “front,” “rear,” “top,” “bottom,” “side,” etc. are used for explanatory purposes in the examples provided to describe the relative position of certain components or positions of components. Furthermore, as would be evident to one of ordinary skill in the art in light of the present disclosure, the terms “substantially” and “approximately” indicate that the referenced element or associated description is accurate to within applicable engineering tolerances.

Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). No element, act, or instruction used herein should be construed as critical or essential unless explicitly described as such.

As used herein, a “heat transfer plate” may refer to a component, device, structure, or the like used to transfer heat. The heat transfer plate may include, or may be created from, one or more materials that rely on heat transfer properties to move heat from a first area to a second area, a first component to a second component, a first material to a second material, or the like. Further, the heat transfer plate may be a component that has a uniform or a non-uniform shape that further enables the transfer of heat. Additionally, or alternatively, the heat transfer plate may include a structure that contains a material or substance (e.g., a fluid, a liquid, a gas, etc.) that may be used in combination with the heat transfer plate to assist in the transfer of heat. Further, the heat transfer plate may include shapes and/or geometries that feature plate-like components. Further still, the heat transfer plate may feature components that increase the surface area of the heat transfer plate in order to effectively transfer heat. In some cases, the heat transfer plate may refer to a cold plate used to cool a specific component or a hot plate used to warm a specific component, such as to attain or maintain a particular temperature or range of temperatures of the specific component (e.g., an electronic device).

As used herein, an “electronic device” may refer to an electronic component used in a computing system, a networking system, or the like that may be used to at least assist in processing data. An electronic device may include a piece of hardware that may be used in a computing system, for example, that may be used directly or indirectly to process data. In this regard, the electronic device may store, transfer, process, aggregate, receive, distribute, or manipulate data. Further, the electronic device may include a discrete piece of hardware that may be used by one or more other components used to assist in processing data. For example, the electronic device may be a portion of a component that is used by a computing system. Further, in some embodiments, the electronic device may include an entire device, component, system, or the like, used to at least assist in processing data. In some embodiments, an electronic device may include a graphics processing unit (GPU), a central processing unit (CPU), a data processing unit (DPU) such as an Nvidia® BlueField® DPU, quantum processing units (QPUs), a plurality of parallel processing units (PPUs), a switch, a network interface controller (NIC), or the like.

Additionally, or alternatively, one or more electronic devices may be included within a data center which may include multiple servers that contain various computing resources (e.g., electronic devices). These resources may include central processing units (CPUs), such as NVIDIA Grace™ CPUs, and graphics processing units (GPUs), such as NVIDIA® H100 Tensor Core GPUs. Each server may be configured to handle specific types of workloads, such as general-purpose computing, data processing, specialized tasks like artificial intelligence (AI) and machine learning (ML) applications, and/or the like. For example, NVIDIA® Tensor Core GPUs may be used to accelerate AI and ML workloads by performing parallel processing of large datasets. The servers may be connected to one or more datacenter switches, allowing the servers to communicate with other systems within the datacenter or external networks. Further, the configuration of the servers may be scalable, allowing for additional servers, electronic devices, and/or computing resources, such as those with NVIDIA® GPUs and CPUs, to be added or removed as needed based on computing requirements. QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

Electronic devices, such as GPUs, CPUs, and DPUs, may produce significant heat during operation. The temperature of the electronic devices may need to be regulated (e.g., cooled) for the electronic devices to maintain safe and/or optimal working temperatures during operation. In some cases, the electronic devices may be liquid-cooled using liquid-cooled cold plates (e.g., heat transfer plates or Manifold Microchannel (MMC)). In some cases, these cold plates use thin copper fins inside a sealed cavity and rely on heat transfer fluid (e.g., cooling fluid) to extract heat generated by the electronic devices. In this regard, the electronic device may be coupled to the cold plate, and a cooling fluid may be used within the sealed cavity of the cold plate to transfer the heat away from the electronic device. The cooling fluid used to extract heat may range from a liquid-based cooling fluid to gaseous cooling fluids. The copper fins of the cold plate in the described example may be spaced apart to create gaps between the fins, referred to as microchannels, through which the cooling fluid may flow. These microchannels may be similar to fins in an air-cooled heatsink. Conventionally, cold plates may use microchannels that are 200 micrometers wide; however, narrower microchannels may be preferable in some applications.

Traditionally, the fluid path within cold plates typically uses either crossflow or split flow designs, wherein the fluid is delivered to the middle of the microchannel fins at a single fluid entrance point and then divided evenly to flow in two directions. These traditional designs and/or cold plate assemblies often encounter issues associated with thermal performance, pressure drop, and clogging. Further, traditional methods are suited for low power densities of less than 1 kW. As device power increases, along with power distribution non-uniformity (e.g., core, input/output devices, high bandwidth memory (HBM)), the fin spacing is expected to be reduced incrementally to increase the available surface area and drive higher fluid velocities that are expected to improve thermal performance. For example, the fin spacing is expected decrease from 200 micrometers to 150 micrometers, then to 100 micrometers, and eventually to 50 micrometers (e.g., the thickness of a human hair). The challenges with traditional flow patterns will grow increasingly worse as the fin spacing is reduced.

Initially, and for avoidance of doubt, embodiments as described herein may be described in reference to the cooling abilities of the solution (e.g., using the heat transfer fluid to cool an electronic device). However, it is to be understood that applications requiring a heating or warm-up period may also be used with the same or similar components. In this regard, the heat transfer applications that are described herein describe heat transfer capabilities of the solution generally, and no limitations on a specific direction of heat transfer (e.g., heat flowing into or out of a component) should apply, unless explicitly stated.

For example, the embodiments described herein may apply to applications where transferring heat away from electronic devices is required, as well as applications that require transferring heat to certain electronic devices that may need to reach a certain temperature before the electronic device may be functional. In a specific example, a CPU may need to be warmed to an operating temperature of ten degrees Celsius prior to operating the CPU. The solutions as described herein may use the same and/or similar components to achieve the warm-up temperatures required of certain electronic components. In this regard, the heat transfer fluid may bring and distribute heat to the electronic device via the heat transfer plate until the electronic device is warmed. In some embodiments, after the warm-up temperature has been achieved, the cooling cycle may be initiated to maintain safe and/or optimal operating temperatures of the electronic device.

Embodiments of the disclosure as described herein may provide for improved devices, systems, and methods for regulating the temperature of electronic devices, circuits, and components, such as graphics processing units (GPUs), central processing units (CPUs), data processing units (DPUs), QPUs, PPUs, and switch chips, while addressing the issues of traditional heat transfer plate solutions.

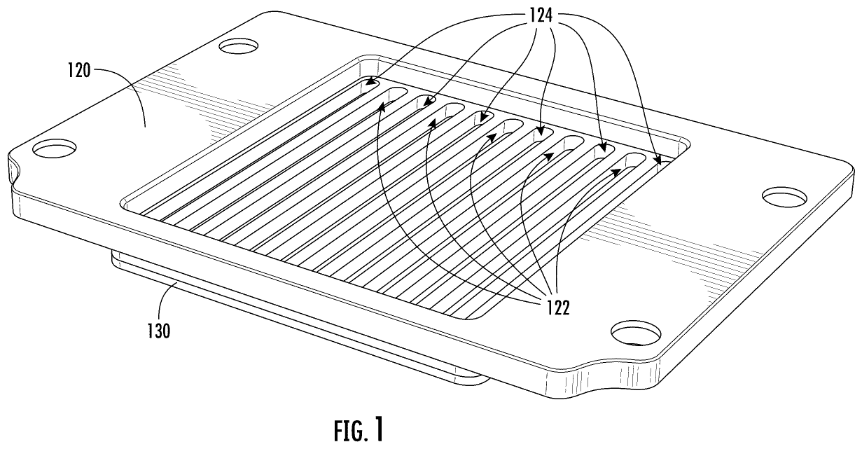

The present disclosure as provided herein may include a system configured to regulate the temperature of electronic devices and to provide enhanced and balanced thermal performance of electronic devices by evenly distributing a fluid within a heat transfer plate. In some embodiments, the system may include a coupler, a distribution manifold, a top cover, a gasket, and/or a heat transfer plate. For example, with reference to FIG. 1, a distribution manifold 120 may be configured to promote even and simultaneous distribution of the heat transfer fluid. The distribution manifold 120 may include flow slots (e.g., entrance flow slots 122 and exit flow slots 124) that may receive the heat transfer fluid. As shown in FIG. 1, the distribution manifold 120 may include a multitude of adjacent flow slots that provide shortened fluid flow paths, promoting more uniform heat transfer across the electronic device. In some embodiments, the system may include one or more attachment couplings used to couple the system to an electronic device. In some embodiments, the system may further include a frame used to couple the heat transfer plate to the distribution manifold. In this regard, and in some embodiments, the system as described herein may be configured to promote temperature regulation of a component which may include a GPU, DPU, CPU, QPU, PPU or other electronic device, as described above.

FIGS. 1-11 illustrate an example embodiment of a system 100 for regulating the temperature of electronic devices. With reference to FIG. 1, the distribution manifold 120 may define a plurality of entrance flow passages 122 configured to receive a heat transfer fluid therethrough, and a plurality of exit flow passages 124 configured to receive the heat transfer fluid therethrough. As used herein, the passage may define an aperture, opening, or slot that allows the heat transfer fluid to pass through. In some embodiments, the passages may define any shape including, but not limited to, the elongated rectangular shape as shown in FIG. 1. In some embodiments, the shape of the entrance flow passages 122 and exit flow passages 124 may be the same, similar, or different, and may be tailored to increase throughput of the heat transfer fluid where needed. In some embodiments, the distribution manifold 120 may be configured for promoting efficient heat transfer fluid flow through the entrance and exit flow passages 122, 124, as described in greater detail below. In some embodiments, for example, the entrance and exit flow passages 122, 124 may be configured to promote even and simultaneous fluid flow as the heat transfer fluid flows through the distribution manifold 120. Further, in some embodiments, the plurality of entrance flow passages 122 may be substantially parallel to adjacent exit flow passages 124. In addition, the entrance and exit flow passages 122, 124 may be designed so as to have the same or similar shape across the distribution manifold 120. For example, FIG. 1 illustrates the entrance flow passages 122 and the exit flow passages 124 having the same or similar design.

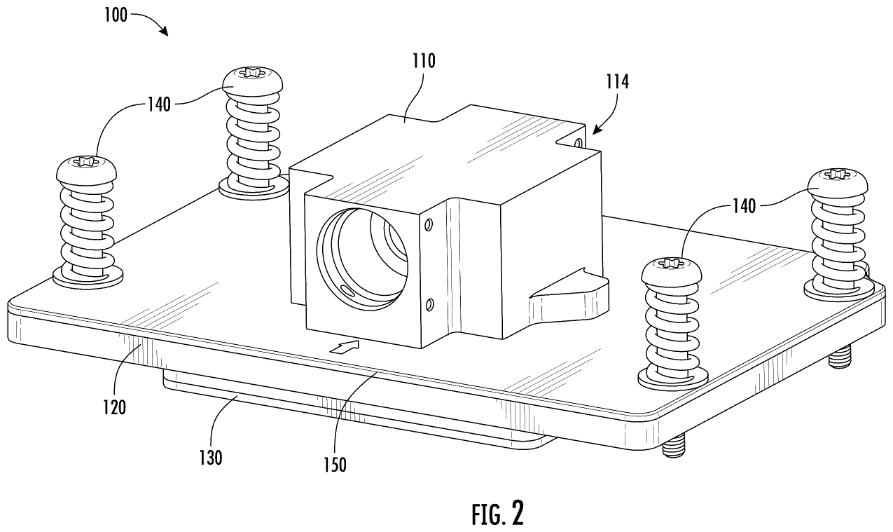

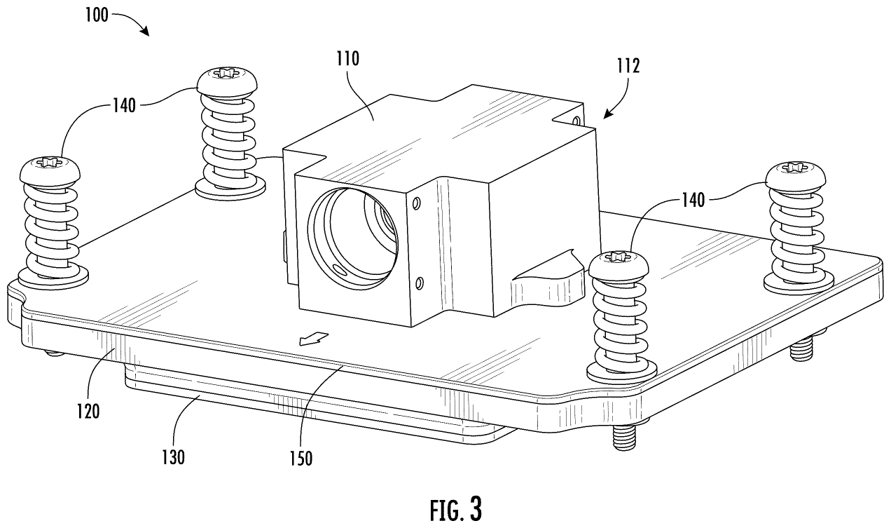

With reference to FIGS. 2 and 3, a coupler 110 may be coupled to a top cover 150, which may be coupled to a distribution manifold 120. In some embodiments, the coupler 110 may be configured to receive the heat transfer fluid from a heat transfer fluid source. As shown in FIG. 2, the coupler 110 may include an inlet 112 for introducing heat transfer fluid into the system 100. For example, the heat transfer fluid may be “cold” heat transfer fluid that will be used to cool an electronic device. In some embodiments, the coupler 110 may be in fluid communication with a plurality of entrance flow passages, wherein the coupler is configured to receive the heat transfer fluid from a source of heat transfer fluid, and wherein the coupler is configured to deliver the heat transfer fluid to the plurality of entrance flow passages. In this regard, and in some embodiments, the heat transfer fluid that flows through the inlet 112 of the coupler 110 may be heat transfer fluid that has not yet extracted heat from the electronic device. Similarly, with reference to FIG. 3, in some embodiments, the heat transfer fluid that has extracted heat (in this example) from the electronic device may flow through the outlet 114 of the coupler 110. In some embodiments, the coupler 110 may be configured to receive the heat transfer fluid from the plurality of exit flow passages. In this regard, the fluid flowing from the outlet 114 may flow to a fluid reservoir (not shown), wherein the fluid may be stored, processed, cooled, heated, or the like.

In some embodiments, the heat transfer fluid that flows through the inlet 112 may be heat transfer fluid that is used to warm the electronic device prior to operation. In other embodiments, when the electronic device needs to be warmed prior to operation, the process as described herein may be run in reverse. In this regard, the heat transfer fluid may flow into the outlet 114 and out of the inlet 112. Additionally, or alternatively, the warming of the electronic device may use the heat stored in the used (e.g., hot) heat transfer fluid stored in the reservoir. For example, the heat transfer fluid stored in the reservoir may be heated from a prior cooling cycle. Running the process in reverse may allow for the electronic device to extract heat from the heat transfer fluid.

In some embodiments, the top cover 150 may include an entrance opening 152, wherein the entrance opening 152 is configured to promote even distribution of the heat transfer fluid to the entrance apertures 162 of the gasket 160. The heat transfer fluid that flows through the entrance opening 152 may be heat transfer fluid received from the inlet 112 of the coupler 110 (shown in FIG. 2). For example, cold heat transfer fluid used to cool an electronic device may flow through the entrance opening 152. Further, in some embodiments, the top cover 150 may include an exit opening 154, wherein the exit opening 154 is configured to receive the heat transfer fluid from the exit apertures 164 of the gasket 160. The heat transfer fluid that flows through the exit opening 154 may be heat transfer fluid that flows to the outlet 114 of the coupler 110 (shown in FIG. 3). For example, after the electronic device has been cooled, the hot heat transfer fluid may flow through the exit opening 154.

The distribution manifold 120 and the top cover 150 may include holes configured to accommodate attachment couplings 140. The attachment couplings 140 may include screws, springs, nuts, bolts, or any other of a variety of components used to couple the system 100 to the electronic device (not shown). In some embodiments, and as shown in FIGS. 2 and 3, the attachment couplings 140 may include a combination of a spring and a screw, which may apply a loading force used to press the top cover 150 into the distribution manifold 120. In this regard, when the top cover 150 and the distribution manifold 120 are coupled, the screw and spring combination (e.g., the attachment couplings 140) may apply a force to press the top cover 150 into the distribution manifold 120. In some embodiments, this attachment force may be used to create a sealing force between the top cover 150 and the distribution manifold 120 so as to ensure that heat transfer fluid within the distribution manifold 120 does not leak from between the top cover 150 and the distribution manifold 120, as will be described in greater detail below. The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2,3,3,3-tetrafluoropropene, 1,1,1,2-tetrafluoroethane and water.

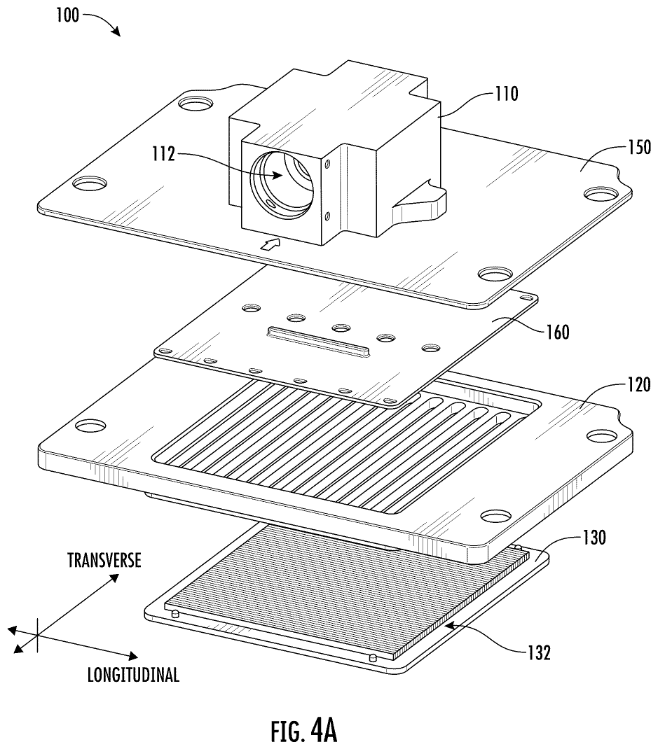

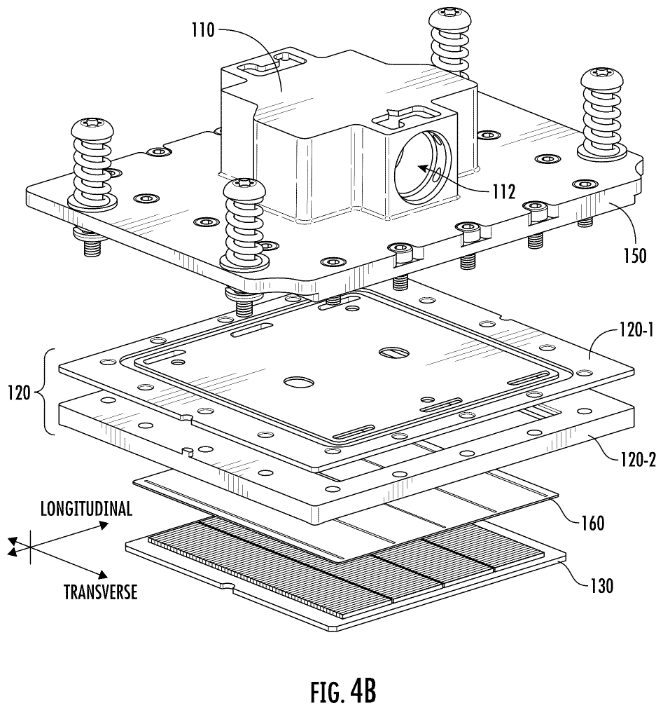

FIG. 4A illustrates an exploded view of the system 100 of FIGS. 2 and 3. In some embodiments, different configurations of the system 100 may include the same, similar, or different components. In some embodiments, the functionalities of the embodiments or configurations may also be the same, similar, or different. In this way, the distribution manifold associated with each of the example embodiments may be configured so as to allow the heat transfer fluid to transfer heat to or from an electronic device.

With reference to FIG. 4A, the system 100 may comprise the heat transfer plate 130, which may include a plurality of heat transfer surfaces, such as fins 132. As used herein, the heat transfer surfaces may include any surface, such as fins 132, used to exchange heat between mediums. For example, heat transfer fins (e.g., the heat transfer fins 132) may be used to exchange heat between the heat transfer fluid and the electronic component or device. In this way, the heat transfer surfaces may be understood by one of ordinary skill in the art as a fin, plate, tube, channel, pin, rod, wall, or the like. In some embodiments, for example, the heat transfer plate 130 may include 235 fins that are 0.100 micrometers thick with a 0.100 micrometer spacing or gap between the fins. Further, in additional embodiments, the fin spacing, thickness, and height may differ to accommodate different thermal needs (e.g., depending on the desired or expected thermal performance of the particular electronic component to be regulated). In this regard, the expected thermal performance of an electronic component may refer to the heating and cooling of the component during operation. Further, the expected thermal performance may include a temperature that a particular electronic device is expected to reach, along with other factors surrounding the electronic device such as proximity to other electronic devices, airflow, time of operation, energy consumption during operation, or the like. For example, the expected thermal performance of the electronic device or component to be regulated may be determined by analyzing one or more thermal measurements of the electronic device. In this regard, the one or more thermal measurements may include historic data.

In this example, the thermal measurements may indicate the electronic device requires a certain flow rate of heat transfer fluid to flow through the heat transfer plate in order to maintain safe operating temperatures. In this regard, these calculations may be used to configure the heat transfer plate (e.g., fin spacing, thickness, and height). Further, in some embodiments, the distribution manifold 120 may couple to the heat transfer plate 130 and may enable the flow of heat transfer fluid through microchannels (e.g., gaps) formed between the fins. In some embodiments, the heat transfer fins associated with the heat transfer plate may be disposed proximate the distribution manifold. As used herein, “proximate” may indicate that the referenced components are next to or near each other. For example, the heat transfer fins being proximate the distribution manifold may provide the heat transfer fins being next to the distribution manifold. Additionally, in some embodiments, the gasket 160 may couple to the distribution manifold 120 and may create a fluid tight seal on top of passages (e.g., entrance flow passages and exit flow passages) defined by the distribution manifold 120, as described in greater detail below. Further, the gasket 160 may have entrance and exit apertures that may control the heat transfer fluid path while also preventing fluid bypass and recirculation that could “short circuit” fluid flow between the passages.

In some embodiments, and as shown in FIG. 4A, the heat transfer fluid may flow from the coupler 110 through a top cover 150. In some embodiments, the top cover 150 may be disposed proximate a bottom surface of the coupler 110 and proximate a top surface of the distribution manifold 120. In some embodiments, the top cover 150 may be coupled (e.g., adhered, welded, fastened, or otherwise attached) to the coupler 110.

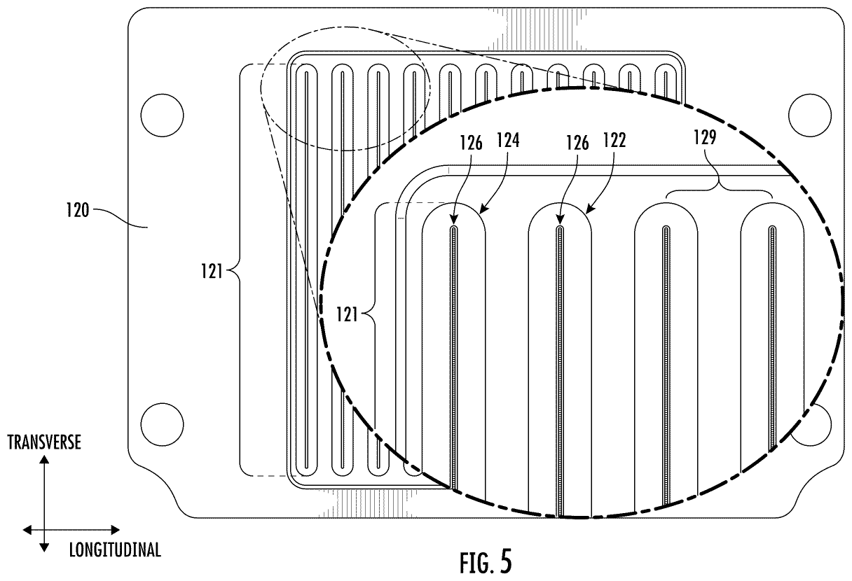

Additionally, or alternatively, and as shown in FIG. 5, in some embodiments a distance 129 between at least one of the plurality of entrance flow passages 122 and an adjacent exit flow passage 124 may be in the range of approximately four millimeters to approximately six millimeters. In this regard, the distance 129 may define the distance between midpoints of the adjacent entrance and exit flow passages 122, 124. In other embodiments, however, the distance may define the distance between adjacent walls of adjacent entrance and exit flow passages 122, 124.

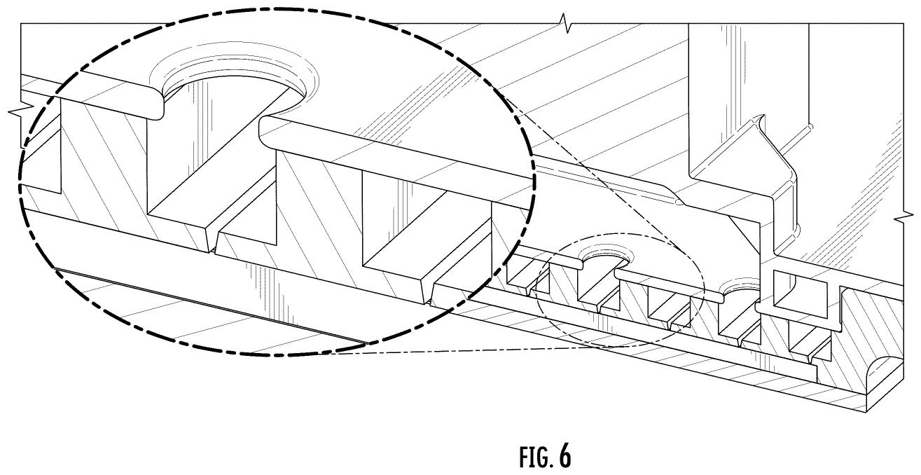

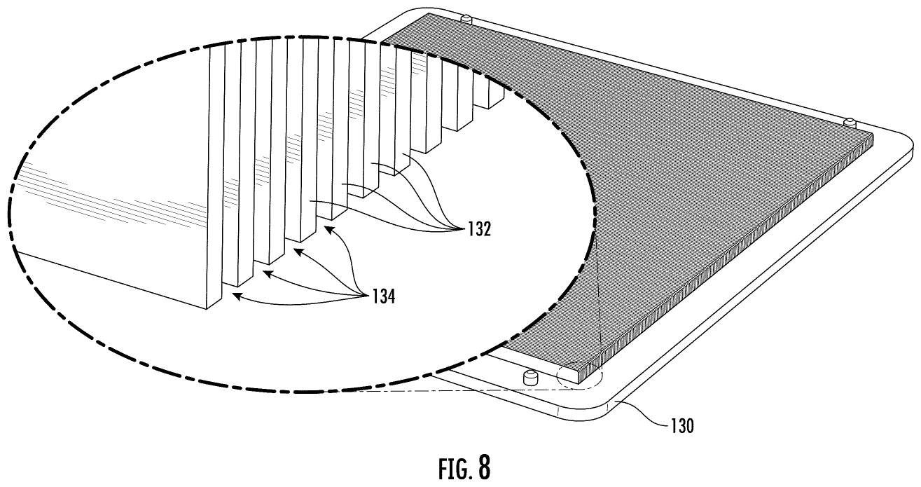

In some embodiments, with reference to FIGS. 5 and 6, each of the entrance flow passages 122 and the exit flow passages 124 may include at least one vertical flow channel 126. In some embodiments, the entrance flow passages 122 and the exit flow passages 124 may be in fluid communication with the plurality of gaps of the heat transfer plate 130 via the vertical flow channels 126. In this regard, the vertical flow channels 126 may be configured to distribute or receive fluid as it flows between the flow passages and the heat transfer plate 130. For example, in some embodiments and as shown in FIG. 8, the heat transfer fins 132 may extend from the heat transfer plate 130 toward the distribution manifold 120. In some embodiments, the plurality of heat transfer fins 132 may define the plurality of gaps 134 therebetween. In this regard, the heat transfer fluid may flow into the gaps 134 created by the plurality of fins 132 of the heat transfer plate 130.

In some embodiments, the length of at least one of the vertical flow channels 126 may be substantially the same length as the passage length 121, as shown in FIG. 5. The length of the vertical flow channel 126 being substantially the same as the passage length 121 may promote even distribution of the heat transfer fluid to the heat transfer plate 130, allowing for more efficient temperature regulation of the electronic device.

In some embodiments, and as shown in FIG. 6, at least one of the vertical flow channels 126 may include a taper 128, wherein a direction of the taper may correspond to a direction of flow of the heat transfer fluid through the respective vertical flow channel 126. In this regard, the taper 128 may, in some embodiments, taper (e.g., the width of the vertical flow channel may get narrower) in the direction of the flow of the heat transfer fluid. For example, the taper 128 of the vertical flow channel 126 associated with an entrance flow passage 122 corresponds to the direction the heat transfer fluid flows through the vertical flow channel 126 (e.g., downward, toward the heat transfer plate 130). In some embodiments, the taper 128 design may include a “nozzle-like” taper of the vertical flow channels 126, in which the width of the vertical flow channel in the direction of flow changes from a wider opening to a narrower opening, which may result in higher velocity flow of the heat transfer fluid as the fluid exits the distribution manifold 120 and enters the heat transfer plate 130. The direction of the taper 128 for other vertical flow channels, however, may not correspond to the flow direction of the heat transfer fluid as it flows within the vertical flow channel 126. For example, as shown in FIG. 6, the vertical flow channel 126 associated with the exit flow passage 124 has a taper 128 in a direction that is opposite to the flow direction of the heat transfer fluid, as the vertical flow channel in this case gets narrower toward the heat transfer plate 130, but the heat transfer fluid flows from the heat transfer plate 130 into the distribution manifold 120.

Additionally, or alternatively, the taper 128 may direct the flow of the heat transfer fluid as the fluid flows into the gaps 134 of the heat transfer plate 130. In some embodiments, the taper 128 may be a uniform taper across all the vertical flow channels 126. In this regard, the taper 128 may slope in a uniform manner throughout each vertical flow channel 126 and/or may also have the same slope across all vertical flow channels 126. In other embodiments, the taper 128 may change within a single vertical flow channel 126 (e.g., along the length 121) and/or may have a different slope as among the plurality of vertical flow channels 126. For example, a single vertical flow channel 126 may have a varying taper 128 based on the expected thermal performance of the component (e.g., electronic device) to be temperature regulated. In this regard, for example, the taper 128 may be configured to allow more heat transfer fluid to flow through one or more of the vertical flow channels 126 located in areas where the electronic device is expected to generate significant heat. Additionally, or alternatively, the taper 128 may be configured to restrict flow of the heat transfer fluid through one or more other vertical flow channels 126 located in areas where the electronic device is expected to generate less heat than other areas.

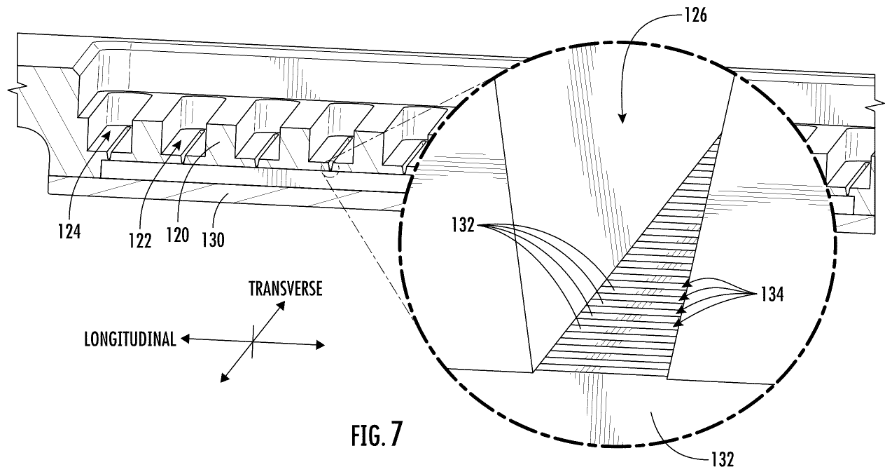

In some embodiments, the heat transfer fluid may enter the heat transfer plate gaps 134 from the vertical flow channel 126, as shown in FIG. 7. The distribution manifold 120 may, for example, define a transverse direction, wherein the plurality of entrance flow passages 122 and the plurality of exit flow passages 124 are aligned with the transverse direction, and a longitudinal direction, wherein the gaps 134 defined by the plurality of heat transfer fins 132 are aligned with the longitudinal direction. In this regard, the heat transfer fluid may flow within the entrance flow passages 122 and the exit flow passages 124 in the transverse direction. As the heat transfer fluid enters the gaps 134 defined by the heat transfer fins 132, the heat transfer fluid may then flow in the longitudinal direction.

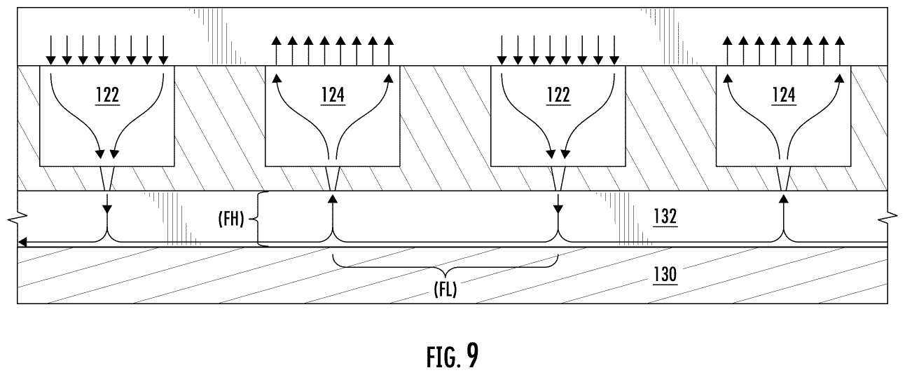

In some embodiments, the fluid flowing into the gaps 134 may result in an impinged heat transfer mechanism. In this regard, the impinging fluid flow may result from the heat transfer fluid being directed by the vertical flow channels 126 and hitting the heat transfer plate 130, creating turbulent fluid flow. In some embodiments, the turbulence generated within the heat transfer fluid may increase the ability of the heat transfer plate 130 to extract heat from the electronic device. Further, as shown in FIG. 9, the path of the heat transfer fluid from the entrance flow passages 122 to the exit flow passages 124 may be a short path. As indicated by the arrows, the heat transfer fluid may flow from the entrance flow passages 122 down to the gaps 134 between the fins 132 to regulate temperature. The fluid may split in two directions and travel the flow length (FL) and then recombine prior to exiting via the exit flow passage 124. The fluid that flows between the fins may regulate temperature by raising or lowering the temperature of the fins, which in turn are transferring heat via the portions of the heat transfer plate 130 that are in contact with or proximate the component to be temperature regulated. In some embodiments, this may include carrying heat away from the fins 132 (e.g., in a scenario where the component is increasing in temperature and the heat transfer plate is transferring heat from the component to the fins).

In some embodiments, the flow length may include the length of the path the fluid travels as it flows within the gaps 134 between an entrance flow passage 122 and an exit flow passage 124. Further, the fin height (FH) may be the height of the fins 132. In some embodiments, the approximate ratio of the flow length (FL) to the fin height (FH) may be approximately 5:1, although other ratios may be used (e.g., 1:1, 2:1, 3:1, 4:1, 6:1, 7:1, 8:1, 9:1, 10:1, and so on). Further, in some embodiments, the solutions as described herein provide for using shorter fins and tighter fin spacing to maintain the necessary velocity to achieve a high heat transfer coefficient. Further, in some embodiments, the solutions as described herein provide for a more compact design compared to traditional designs.

The flow pattern across the cooling fins is different than conventional solutions which may solve the issues associated with thermal performance, pressure drop, and clogging risks. In particular, the flow length ratio may be substantially shorter than conventional solutions. For example, the thermal performance of the solutions described herein may be due to the shorter flow length FL, which enables heat transfer fluid to cycle through the heat transfer plate 130 at a higher rate. For example, when the heat transfer fluid is extracting heat from an electronic device, the cold heat transfer fluid may be distributed in more areas (compared to conventional designs) due to the increased number of entrance flow passages 122 across the heat transfer plate 130. Additional entrance flow passages 122 allow more heat transfer fluid to flow through the heat transfer plate 130, which results in extracting more heat from the electronic device in the current example. In this regard, the configuration described herein results in more uniform, balanced temperatures with the same inlet temperature fluid dispersed across the device, which results in a more uniform temperature across the electronic device. The uniform temperature of the electronic device may increase the functionality of variable software load conditions of the electronic device (e.g., core intensive, High Bandwidth Memory intensive, etc.).

Further, an increase in the number of entrance flow passages 122 and exit flow passages 124 decreases the pressure drop across the heat transfer plate 130, as compared to designs with fewer flow passages. In this regard, a pump cycling the heat transfer fluid throughout the system may not require as high of a power consumption as compared with conventional designs without the plurality of entrance flow passages and exit flow passages.

Further still, the configuration of the plurality of entrance flow passages 122 and exit flow passages 124 reduces the risk of clogging within the gaps 134 of the heat transfer plate 130. For example, particles, dust, or other objects may enter into the fin gaps 134 during operation of the system 100. These particles may clog the gap 134, reducing or eliminating the flow of the heat transfer fluid within that particular gap 134. By increasing the number of entrance flow passages 122 and exit flow passages 124, the solution described herein relies on each gap 134 less, reducing the likelihood of clogging adversely affecting the ability of the system 100 to regulate the temperature of the electronic device.

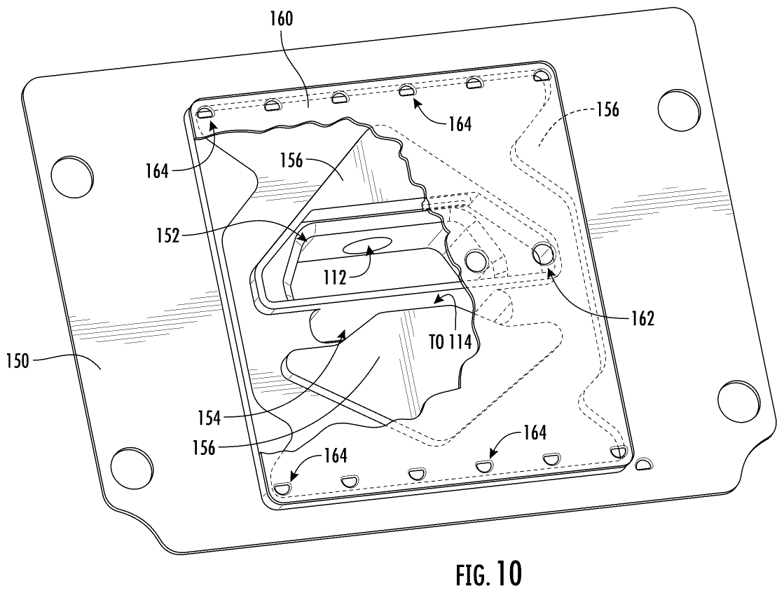

In some embodiments, the entrance flow passages 122 of the distribution manifold 120 may receive the heat transfer fluid from entrance apertures 162 of the gasket 160, as shown in FIG. 10. In some embodiments, the gasket 160 may be configured to be disposed proximate the distribution manifold 120. Further, the gasket 160 may be configured to distribute the heat transfer fluid to the plurality of entrance flow passages 122 and may be configured to receive the heat transfer fluid from the plurality of exit flow passages 124 (shown in FIGS. 1 and 4). Further still, the gasket 160 may be configured to form a seal between the entrance flow passages 122 and the exit flow passages 124 to prevent a bypass of the heat transfer fluid, as described above.

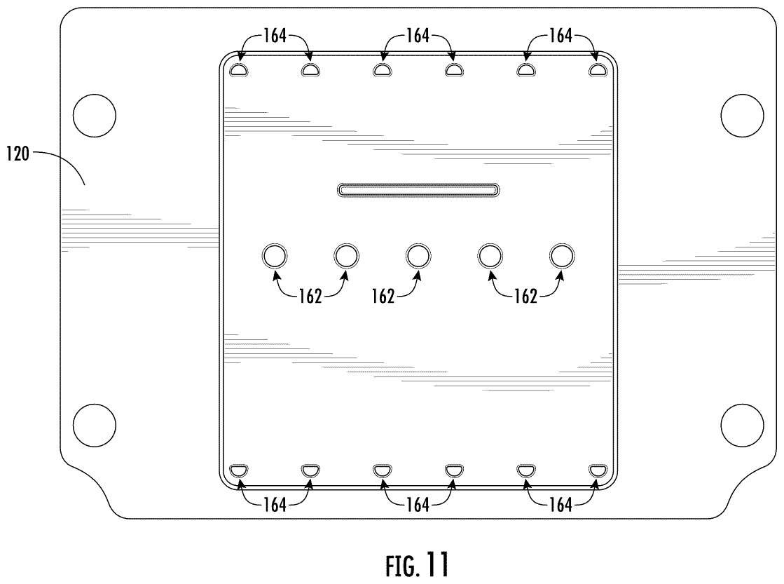

Additionally, or alternatively, the gasket 160 may be configured to control an inflow of the heat transfer fluid to the entrance flow passages 122 and to control an outflow of the heat transfer fluid from the exit flow passages 124. In this regard, the gasket 160 may include entrance apertures 162 configured to distribute the heat transfer fluid to the entrance flow passages 122. For example, FIG. 11 shows a top view of the gasket 160 seated against or coupled to the distribution manifold 120. The gasket 160 may include entrance apertures 162 that are aligned with the entrance flow passages 122 of the distribution manifold 120. Further, the gasket 160 may include exit apertures 164 that are aligned with the exit flow passages 124 of the distribution manifold 120. In some embodiments, the gasket 160 may include at least two exit apertures 164, wherein each exit aperture 164 is configured to be aligned with an end of a respective exit flow passage 124.

In some embodiments, and in combination with the apertures of the gasket 160, the apertures 162, 164 may be positioned at the far end of each flow passage 122, 124 of the distribution manifold 120 to provide for a “reverse return” Tichelmann fluid circuit that helps provide a balanced distribution between the inlet and outlet of the fluid regardless of the distance the fluid travels from the main inlet 112 and outlet 114 of the coupler 110. For example, in some embodiments, the path of the fluid flow from the inlet 112 to the gasket 160 may be the same distance as the path of the fluid flow from the gasket 160 to the outlet 114. In this regard, the Tichelmann fluid circuit may equalize balances of fluid flow by having equal fluid path lengths while flowing out one path and returning via another path.

In some embodiments, and as shown in FIG. 10, the gasket 160 may be aligned with a fluid director 156 of the top cover 150. In some embodiments, the fluid director 156 may control the fluid flow from the inlet 112 of the coupler 110 to the entrance apertures 162 located approximately in the middle of the gasket 160. In this regard, the fluid director 156 may include a structure, component, extrusion, or the like, coupled to or protruding from the top cover 150. The fluid director 156 may separate the inflowing heat transfer fluid (e.g., the fluid that will flow through the entrance opening 152) from the outflowing heat transfer fluid (e.g., the fluid that will flow from the exit opening 154). For example, when cooling an electronic device, the fluid director 156 may separate the cold, unused fluid from the hot, used fluid. Further, the fluid director 156 may direct fluid flow from the exit apertures 164, located proximate an edge of the gasket 160, to the outlet 114. In this regard, and in some embodiments, the apertures (e.g., the entrance apertures 162 and exit apertures 164) of the gasket 160 may be configured to align with the fluid directing structures of the fluid director 156.

In some embodiments, and as shown in FIG. 4B, the distribution manifold 120 may have a top portion 120-1 and a bottom portion 120-2. In some embodiments, the top portion 120-1 may be configured to direct the flow of the heat transfer fluid to the heat transfer plate 130. Further, in some embodiments, the bottom portion 120-2 may include a frame that positions and aligns the gasket 160 and the heat transfer plate 130. In this regard, the gasket 160 may be positioned between the bottom portion of the distribution manifold 120-2 and the heat transfer plate 130. Further, in some embodiments, the gasket may be configured to distribute the heat transfer fluid to the plurality of gaps. In some embodiments, the gasket may be configured to receive the heat transfer fluid from the plurality of gaps.

Additionally, or alternatively, in some embodiments, the gasket 160 may be configured to form a seal between each of the plurality of heat transfer surfaces to prevent a bypass of the heat transfer fluid. In some embodiments, the gasket may be further configured to control an inflow of the heat transfer fluid to the plurality of gaps and control an outflow of the heat transfer fluid from the plurality of gaps. For example, the gasket 160 may form a seal on the tops of the heat transfer surfaces as to prevent the heat transfer fluid from flowing between the plurality of gaps. In some embodiments, the apertures of the gasket 160 may include slots, holes, or passages that are substantially the same length as the gasket 160 in the transverse direction. For example, the apertures may extend in the transverse direction over each of the plurality of heat transfer surfaces and gaps extending in the longitudinal direction.

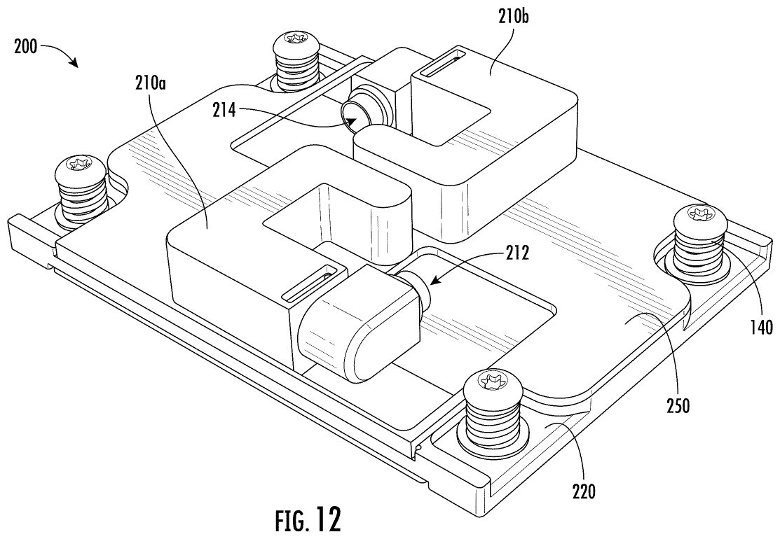

In other embodiments, and as shown in FIG. 12, different configurations of a system for regulating the temperature of electronic devices may be provided. For example, a system 200 may be used, which may include one or more of the components discussed with regard to the system 100. For instance, with respect to FIG. 12, the system 200 may include attachment couplings 140, couplers 210, an inlet 212, an outlet 214, a top cover 250, and a distribution manifold 220. Representations of such components may include varying geometries and configurations between the systems (e.g., the system 100 and the system 200); however, the functionalities of the components may be the same or similar.

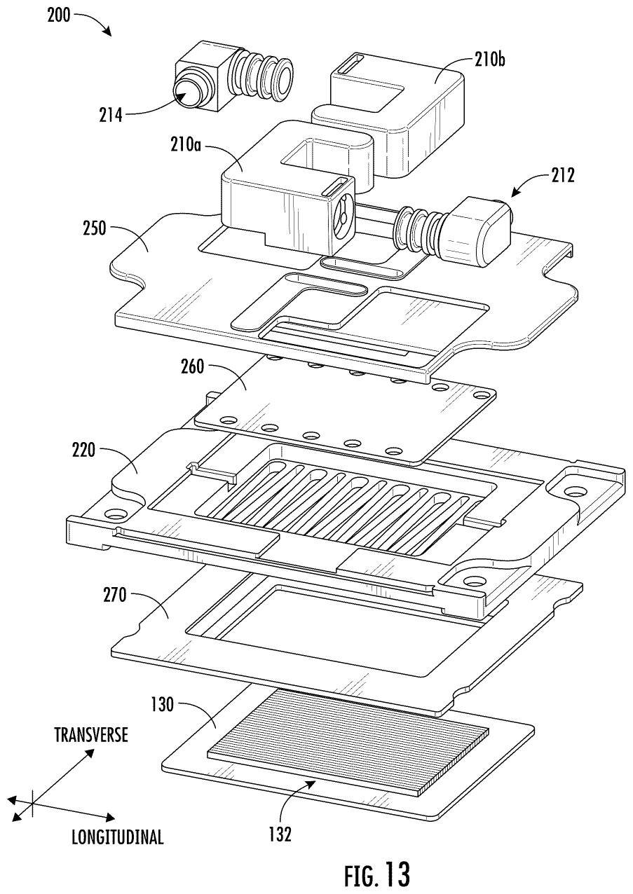

For example, in some embodiments, the system 200 may include two couplers 210a, 210b, one of which 210a is configured to receive the heat transfer fluid from the inlet 212 and the other 210b configured to deliver the heat transfer fluid to the outlet 214. The inlet 212 may be coupled or attached to the coupler 210a and also may be configured to receive the fluid from a fluid source (not shown). Further, in some embodiments, the inlet 212 may be a separate component that is removably attached to the coupler 210a, such as via a threaded interface, as shown in FIG. 13. The outlet 214 may be coupled or attached to the other coupler 210b and may be configured to receive the fluid from the top cover 250 via the coupler 210b. Similarly, the outlet 214 may be a separate component that is removably attached to the coupler 210b, such as via a threaded interface, as shown in FIG. 13. In some embodiments, the couplers 210a, 210b may couple to the top cover 250 via a weld, coupling mechanism, adhesive, or the like so as to secure or otherwise attach the couplers 210a, 210b to the top cover 250. Further, the couplers 210a, 210b may include a path therethrough configured to transfer the fluid between the inlet 212 or outlet 214 and the top cover 250.

Further, as shown in FIG. 13, the system 200 may have at least as many components as the system 100 with respect to FIG. 4A. For example, in some embodiments, the system 200 may include a frame 270 that may be a structure used to create a four-walled perimeter seal around the fins 132 of the heat transfer plate 130. The frame 270 may couple the heat transfer plate 130 to the distribution manifold 220. In this regard, the frame 270 may seat, attach, or align the heat transfer plate 130 to the distribution manifold 220 and may create a peripheral seal that prevents leakage of the heat transfer fluid as it flows between the distribution manifold 220 and the heat transfer plate 130.

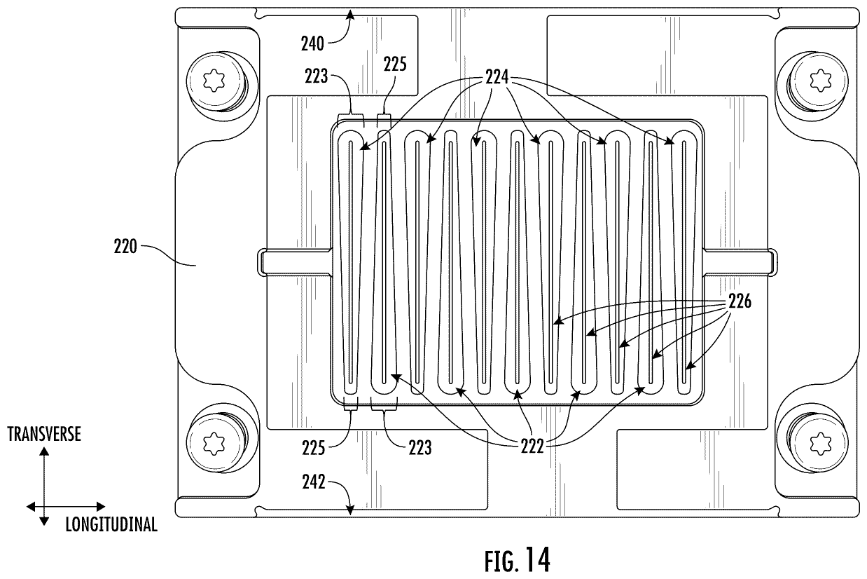

Further, in some embodiments, the distribution manifold 220 may have tapered entrance and/or exit flow passages 222, 224, as shown in FIG. 14. In some embodiments, the distribution may define a first end 240 and a second end 242, wherein at least one of the plurality of entrance flow passages 222 is narrower proximate the first end 240 and is wider proximate the second end 242. Further, in some embodiments, at least one of the plurality of exit flow passages 224 may be wider proximate the first end 240 and narrower proximate the second end 242. For example, one or more of the entrance and exit flow passages 222, 224 may have a wider end (e.g. 4 mm) and a narrower end (e.g. 2 mm), which may define a taper along the transverse axis of the respective flow passage. In this regard, the exit flow passages 224 may have a wide end 223 proximate a first end 240 of the distribution manifold 220 and a narrow end 225 proximate a second side 242 of the distribution manifold 220. In some embodiments, the entrance flow passages 222 may have a similar taper but flipped along the longitudinal axis. For example, the wide end of the entrance flow passages 222 may be proximate the second end 242 of the distribution manifold 220 and the narrow end may be proximate the first end 240. In some embodiments, and as a non-limiting example, the wide end may be approximately four millimeters wide and the narrow end may be approximately two millimeters wide, although other dimensions are contemplated. In this regard, the dimensions chosen for the wide and narrow ends of the entrance and/or exit flow passages 222, 224 may provide for an even velocity of flow of the heat transfer fluid along the entire length of the flow passages, which may promote uniform flow distribution.

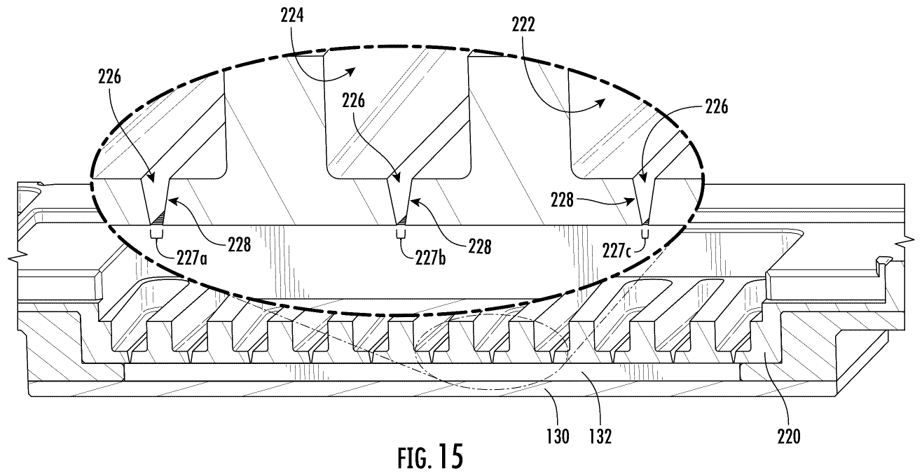

Further, as shown in FIG. 15, in some embodiments, the vertical flow channels 226 may include a variable nominal width (e.g., the widths 227a, 227b, and 227c). In this regard, the width 227a, 227b, and 227c may be the width of an opening of the vertical flow channel 226 proximate the heat transfer plate 130 that controls the flow of the heat transfer fluid as it passes between the distribution manifold 220 and the heat transfer plate 130. A nominal width may represent a number of widths along a vertical flow channel. For example, even if the width changes along the length of the vertical flow channel, it may be representative of an average width, a mean width, etc. Further, in some embodiments, the variable nominal width may vary between the one or more vertical flow channels. For example, the variable nominal widths 227a, 227b, and 227c may be the same or different for different vertical flow channels. In some embodiments, each of the variable nominal widths 227a, 227b, and 227c may be different sized openings, allowing for differing amounts of heat transfer fluid to flow between the distribution manifold 220 and the heat transfer plate 130. By way of non-limiting example, the variable nominal width 227a may be approximately 250 micrometers, 227b may be approximately 150 micrometers, and 227c maybe approximately 100 micrometers. Further, in some embodiments, the widths as described herein may be tailored for unique thermal performances of electronic devices.

For example, in some embodiments, a nominal width of at least one of the vertical flow channels 226 may be based on an expected thermal performance of a component (e.g., the electronic device) to be temperature-regulated proximate the at least one vertical flow channel 226. In this regard, the nominal width may define the width of the vertical flow channel 226 and be based on the expected thermal performance of an electronic device coupled to the heat transfer plate 130. For example, in areas where the electronic device may produce more heat, the width of the vertical flow channel 226 may be wider (e.g., as shown by 227a) to allow more cooling fluid to pass into the heat transfer plate 130. Further, in areas where the electronic device may generate less heat, the width of the vertical flow channel 226 may be narrower, such as width 227c.

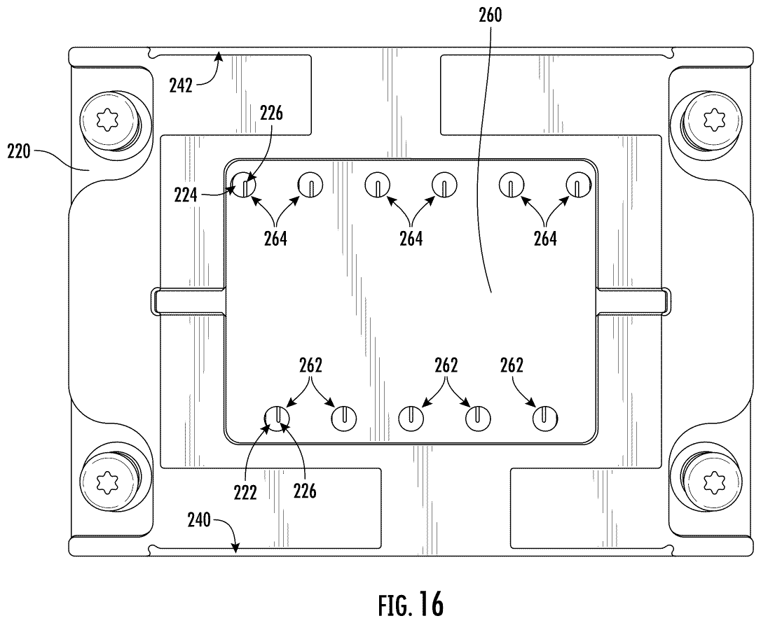

Further, with reference to FIG. 16, in some embodiments, the gasket 260 may be configured with the entrance apertures 262 proximate the first side 240 of the distribution manifold 220 and the exit apertures 264 proximate the second side 242 of the distribution manifold 220. In this regard, the entrance and exit apertures 262, 264 may be aligned with the wide ends of the respective tapered flow passages. For example, the wide end 223 of the entrance flow passages 222 may be aligned with the entrance apertures 262 while the wide end 223 of the exit flow passages 224 may be aligned with the exit apertures 264.

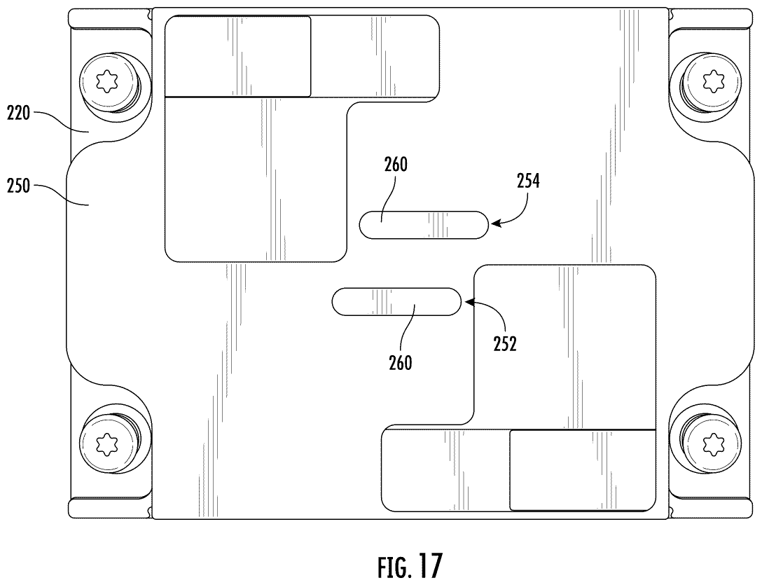

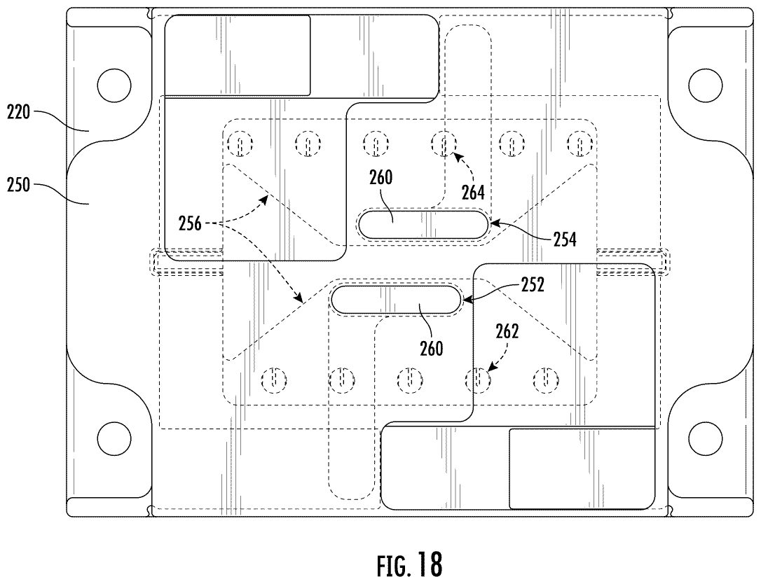

FIG. 17 illustrates a top view of the top cover 250 coupled to the distribution manifold 220 wherein the top cover 250 includes an entrance opening 252 and an exit opening 254 that allows the heat transfer fluid to flow from the couplers to the gasket 260. In some embodiments, and as shown in FIGS. 17 and 18, the entrance opening 252 and the exit opening 254, in combination with the fluid director 256, may be positioned to deliver the heat transfer fluid to the entrance apertures 262 and the exit apertures 264 of the gasket 260, respectively. For example, fluid coming into the system may flow from the entrance opening 252 and be directed, via the fluid director 256, to the entrance apertures 262 of the gasket 260. Similarly, fluid that has cycled through the system may flow through the exit apertures 264 and be directed by the fluid director 256 to the exit opening 254. In this regard, the fluid director 256 may prevent the used and unused fluid from crossing over or intermingling as it flows from the openings of the top cover 250 through the gasket 260.

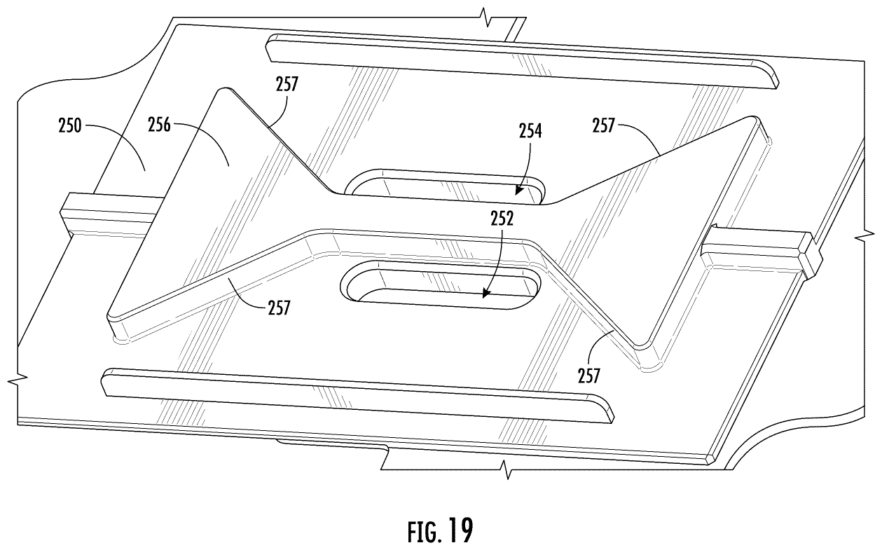

Further, as shown in a bottom perspective view of the top cover 250 in FIG. 19, the fluid director 256 may include a raised or extruded portion of the top cover 250 that is used to separate the fluid flowing from the entrance opening 252 from the fluid flowing to the exit opening 254. Further, the fluid director 256 may include configurations that promote efficient fluid flow through the top cover 250. For example, the fluid director 256 may include one or more angled walls 257 that are configured to promote even and steady fluid flow through the top cover 250. In this regard, and in some embodiments, the angled walls 257 may promote laminar flow and reduce turbulent fluid flow as the heat transfer fluid flows within the top cover 250.

Further, in specific embodiments, a microchannel design may have 200 micrometer fin spacing, along with 100 micrometer thick and 150 micrometer tall fins. If the design includes 200 micrometer fin spacing and a flow passage that is 200 micrometers wide where the fluid enters, the total flow cross-sectional area would be 8 mm\hat{ }2. If the fin spacing were decreased to 50 micrometers, the number of gaps between the fins would increase by 100%, but the total flow area would decrease by 50%.

In a specific example, with reference to Table 1 below, and using the same 50 micrometer gap between the fins, embodiments of the present disclosure may use multiple parallel flow passages (e.g., seven entrance flow passages 122 and seven exit flow passages 124 in this example) to provide a significant increase in the total flow entrance area. In this regard, the total flow entrance area may increase by approximately 350% (14 mm\hat{ }2 vs. 4 mm\hat{ }2) more than third iteration split flow designs. Compared to traditional solutions, embodiments of the present disclosure reduce the clogging risk due to larger total flow cross section inlet area.

TABLE 1
Flow Area Calculations

| | | | | | | Total Fluid |
|---|---|---|---|---|---|---|
| | | | | | Fluid Entrance | Entrance |
| | | | | | Slot Width | Cross- |
| | | Flow | Fin | | (micrometer) × # | Section |
| | Solution | Channel | Thickness | Fin Spacing | of parallel | Area |
| Iteration | Description | Quantity | (micrometer) | (micrometer) | channels | (mm\hat{ }2) |
| 1 | Split Flow G1 | 200 | 100 | 200 | 200 × 1 | 8 |
| 2 | Split Flow Future | 300 | 100 | 100 | 200 × 1 | 6 |
| | G2 | | | | | |
| 3 | Split Flow Future | 400 | 100 | 50 | 200 × 1 | 4 |
| | G3 | | | | | |
| 1 | New Manifold | 300 | 100 | 100 | 100 × 7 | 21 |
| | Microchannel | | | | | |
| | (MMC) G1 | | | | | |
| 2 | MMC Future G2 | 400 | 100 | 50 | 100 × 7 | 14 |

Further, with reference to Table 2 below, a comparison of the thermal performance (as determined by a computational fluid dynamics (CFD) model) of split flow cold plates to a manifold microchannel (MMC) cold plate is provided.

In Example Configuration 1, a split flow cold plate is used for a conventional high-power device, while in Example Configuration 2 a different cold plate with the same split flow fluid pattern is used for a next generation high-power device. In Example Configuration 3, a simulated cold plate according to embodiments of the present disclosure is used that was designed using the same basic physical characteristics as the cold plate in Example Configuration 2, with the exception of the slot length and the implementation of an MMC design. More specifically, the following key characteristics apply to the various cold plates.

Example Configuration 1 provides for a split flow cold plate with 200 micrometer wide vertical flow channels, 200 micrometer thick fins, and approximately a 25 millimeter channel length. Example Configuration 2 provides for a split flow cold plate with 100 micrometer wide channels, 200 micrometer thick fins, and approximately a 26 millimeter channel length. Example Configuration 3 provides for a MMC cold plate with 100 micrometer wide channels, 100 micrometer thick fins, and approximately a 4-6 millimeter channel length.

For the CFD models, the following key assumptions were made. A 125 W/cm\hat{ }2 of uniform power was applied to a die size of approximately 25 mm×32.5 mm, and a 40 C inlet of 25% propylene glycol/water (PG25) was used. The improvement in thermal performance is shown at a flow rate of 1.5 liters per minute (1 pm). At this flow rate, the maximum junction temperature (Tj, max) for Example Configuration 1 is 89 C, compared to 85.4 C for Example Configuration 2 and 78 C for Example Configuration 3.

Further, with respect to Table 3 below, results from a CFD program used to review the flow pattern through the flow passages of the distribution manifold is provided. The design iteration analyzed used 7.5 entrance flow passages and 7.5 exit flow passages. The “half” passage is a by-product of the construction and goal to maximize the use of the heat transfer fins. The flow per channel was well balanced, seven passages predicted to be within +/−2.5% of each other. The end half passage resulted in just slightly over half the flow of the full passages per design intent.

Embodiments of the present disclosure show how the multitude of parallel flow passages may promote even distribution the heat transfer fluid over the entire device and provide for a method to customize the flow distribution depending on device power density. The large quantity of flow passages combined with a short flow path between the entrance and exit of the fins reduces the pressure drop by more than 500% compared to conventional split flow configurations and even greater improvements over other split flow solutions. Additionally, these design features provide the benefit of reducing the clogging risk with the proportionally larger flow entrance area compared to conventional approaches. Furthermore, decreased temperature variations can offer other benefits such as improved thermal interface grease pump out risks.

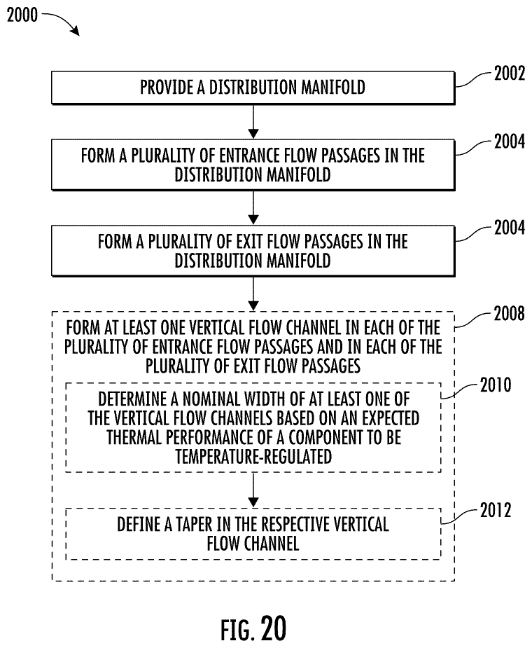

In some embodiments, a method for making a distribution manifold to promote even and simultaneous delivery of heat transfer fluid is provided, as shown in FIG. 20. In some embodiments, the method shown in process flow 2000 may include, as shown in block 2002, providing a distribution manifold. Further, as shown in block 2004, the method may include forming a plurality of entrance flow passages in the distribution manifold, wherein the plurality of entrance flow passages is configured to receive a heat transfer fluid therethrough. In some embodiments, and as shown in block 2006, the method may include forming a plurality of exit flow passages in the distribution manifold, wherein the plurality of exit flow passages is configured to receive the heat transfer fluid therethrough. In some embodiments, the distribution manifold is configured to be disposed proximate a heat transfer plate comprising a plurality of heat transfer fins, wherein the plurality of heat transfer surfaces extends from the heat transfer plate toward the distribution manifold, and wherein the plurality of heat transfer surfaces defines a plurality of gaps therebetween. In some embodiments, the plurality of entrance flow passages is configured to deliver the heat transfer fluid to the plurality of gaps. In some embodiments, the plurality of exit flow passages is configured to receive the heat transfer fluid from the plurality of gaps. The distribution manifold may thus be configured to promote even and simultaneous delivery of the heat transfer fluid to the plurality of gaps, as described above.

In some embodiments, the distribution manifold defines a first end and a second end, wherein forming the plurality of entrance flow passages comprises forming at least one of the plurality of entrance flow passages to be narrower proximate the first end and wider proximate the second end. In some embodiments, forming the plurality of exit flow passages comprises forming at least one of the plurality of exit flow passages to be wider proximate the first end and narrower proximate the second end.

In some embodiments, and as shown in block 2008, the method may further include forming at least one vertical flow channel in each of the plurality of entrance flow passages and each of the plurality of exit flow passages such that the plurality of entrance flow passages and the plurality of exit flow passages are in fluid communication with the plurality of gaps via the vertical flow channels.

In some embodiments, forming the vertical flow channels comprises forming at least one of the vertical flow channels to have a variable nominal width.

In some embodiments, and as shown in block 2010, forming the vertical flow channels comprises determining a nominal width of at least one of the vertical flow channels based on an expected thermal performance of a component to be temperature-regulated proximate the at least one vertical flow channel.

In some embodiments, and as shown in block 2012, forming the vertical flow channels comprises defining a taper in the respective vertical flow channel, wherein a direction of the taper corresponds to a direction of flow of the heat transfer fluid through the respective vertical flow channel.

In some embodiments, each of the plurality of entrance flow passages and each of the plurality of exit flow passages defines a passage length, wherein forming the vertical flow channels comprises forming at least one of the vertical flow channels to have a length that is substantially the same as the passage length.

In some embodiments, the distribution manifold may define a transverse direction, and forming the plurality of entrance flow passages and the plurality of exit flow passages may comprise aligning the plurality of entrance flow passages and the plurality of exit flow passages with the transverse direction. In some embodiments, the distribution manifold may define a longitudinal direction, wherein the gaps defined by the plurality of heat transfer fins are aligned with the longitudinal direction.

In some embodiments, forming the plurality of entrance flow passages comprises forming each of the plurality of entrance flow passages to be substantially parallel to an adjacent exit flow passage.

In some embodiments, forming the plurality of entrance flow passages and the plurality of exit flow passages comprises forming the plurality of entrance flow passages and the plurality of exit flow passages such that a distance between at least one of the plurality of entrance flow passages and an adjacent exit flow passage is in the range of approximately four millimeters to approximately six millimeters.

In yet another embodiment, a method is provided. In some embodiments, the method may include providing a distribution manifold. In some embodiments, the method may include forming a plurality of entrance flow passages in the distribution manifold, wherein the plurality of entrance flow passages is configured to receive a heat transfer fluid therethrough. In some embodiments, the method may include forming a plurality of exit flow passages in the distribution manifold, wherein the plurality of exit flow passages is configured to receive the heat transfer fluid therethrough. In some embodiments, the distribution manifold may be configured to be disposed proximate a heat transfer plate comprising a plurality of heat transfer fins, wherein the plurality of heat transfer surfaces extends from the heat transfer plate toward the distribution manifold, and wherein the plurality of heat transfer surfaces defines a plurality of gaps therebetween. In some embodiments, the plurality of entrance flow passages may be configured to deliver the heat transfer fluid to the plurality of gaps. In some embodiments, the plurality of exit flow passages may be configured to receive the heat transfer fluid from the plurality of gaps. In some embodiments, the distribution manifold may be configured to promote even and simultaneous delivery of the heat transfer fluid to the plurality of gaps.

In some embodiments, the distribution manifold may define a first end and a second end, wherein forming the plurality of entrance flow passages comprises forming at least one of the plurality of entrance flow passages to be narrower proximate the first end and wider proximate the second end.

In some embodiments, the distribution manifold may define a first end and a second end, wherein forming the plurality of exit flow passages comprises forming at least one of the plurality of exit flow passages to be wider proximate the first end and narrower proximate the second end.

In some embodiments, the method may further include forming at least one vertical flow channel in each of the plurality of entrance flow passages and each of the plurality of exit flow passages such that the plurality of entrance flow passages and the plurality of exit flow passages are in fluid communication with the plurality of gaps via the vertical flow channels.

In some embodiments, forming the vertical flow channels may include forming at least one of the vertical flow channels to have a variable nominal width.

In some embodiments, forming the vertical flow channels may include determining a nominal width of at least one of the vertical flow channels based on an expected thermal performance of a component to be temperature-regulated proximate the at least one vertical flow channel.

In some embodiments, forming the vertical flow channels may include defining a taper in the respective vertical flow channel, wherein a direction of the taper corresponds to a direction of flow of the heat transfer fluid through the respective vertical flow channel.

In some embodiments, each of the plurality of entrance flow passages and each of the plurality of exit flow passages may define a passage length, wherein forming the vertical flow channels comprises forming at least one of the vertical flow channels to have a length that is substantially the same as the passage length.

In some embodiments, the distribution manifold may define a transverse direction, wherein forming the plurality of entrance flow passages and the plurality of exit flow passages comprises aligning the plurality of entrance flow passages and the plurality of exit flow passages with the transverse direction. In some embodiments, the distribution manifold may define a longitudinal direction, wherein the gaps defined by the plurality of heat transfer fins are aligned with the longitudinal direction.

In some embodiments, forming the plurality of entrance flow passages may include forming each of the plurality of entrance flow passages to be substantially parallel to an adjacent exit flow passage.

In some embodiments, forming the plurality of entrance flow passages and the plurality of exit flow passages may include forming the plurality of entrance flow passages and the plurality of exit flow passages such that a distance between at least one of the plurality of entrance flow passages and an adjacent exit flow passage is in the range of approximately four millimeters to approximately six millimeters.

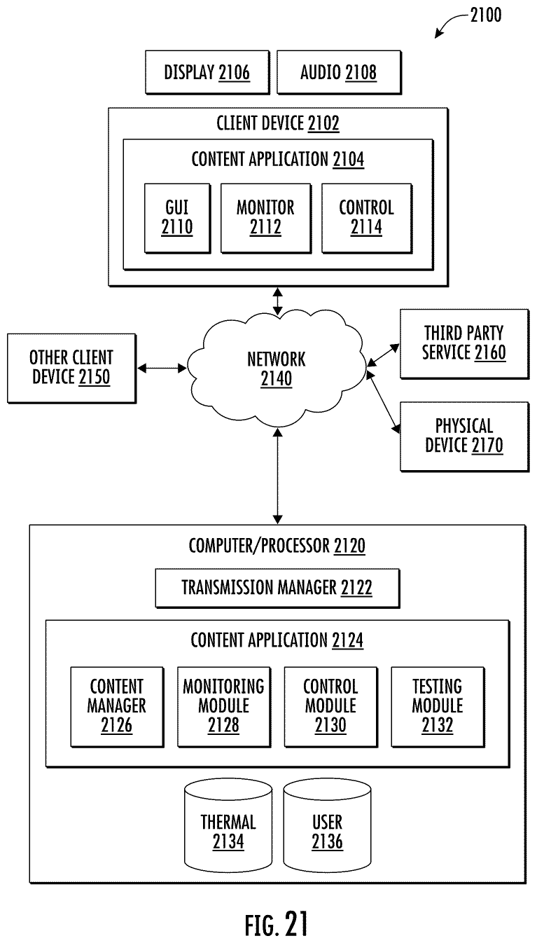

FIG. 21 illustrates an example network configuration 2100 of components that can be used to implement aspects of various embodiments, such as to provide, generate, modify, encode, process, fuse, and/or transmit generated image data, calculated measurements, or other such content. In at least one embodiment, a client device 2102 can generate or receive data for a session using components of a content application 2104 on the client device 2102 and data stored locally on that client device. In at least one embodiment, a content application 2124 executing on a computer or processor 2120 (e.g., a cloud server or control system) may initiate a session associated with at least one client device 2102 (e.g., a vehicle or robot), as may use a session manager and user data stored in a user database 2136, and can cause content such as liquid coolant or server thermal data to be selected and/or retrieved from a repository 2134 to be used by a testing module 2132 to calculate one or more performance metrics for a monitoring module 2128, which can provide flow data or thermal data to a control module 2130 to control a flow or temperature, in an environment where the data is to be used to determine appropriate operation. A content manager 2126 may work with at these various modules to perform testing and analysis, and potentially instruct any actions to be taken in response to a performance metric failing to satisfy an operational requirements. At least a portion of this data or instructional content can be transmitted to the client device 2102 and/or a physical device 2170 using an appropriate transmission manager 2122 to send by download, streaming, or another such transmission channel. An encoder may be used to encode and/or compress at least some of this data before transmitting to the client device 2102. In at least one embodiment, the client device 2102 receiving such content can provide this content to a corresponding content application 2104, which may also or alternatively include a graphical user interface 2110, a flow monitor module 2112, and a control module 2114 for use in providing, synthesizing, rendering, compositing, modifying, or using content for presentation, navigation, control, (or other purposes) on or by the client device 2102, such as may be transmitted to the physical device 2170.

In some embodiments, the computer/processor 2120 and client device 2102 may be able to communicate directly without needing to transmit data over a network 2140, in order to avoid issues with latency and availability, etc. A decoder may also be used to decode data received over the network 2140 for presentation via client device 2102, such as imaging content or performance metrics through a display device 2106 and audio, such as corresponding sounds or synthesized speech, through at least one audio playback device 2108, such as speakers or headphones. In at least one embodiment, at least some of this content may already be stored on, rendered on, or accessible to client device 2102 such that transmission over a network 2140 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 2120, or user database 2136, to the client device 2102. In at least one embodiment, at least a portion of this content can be obtained, enhanced, and/or streamed from another source, such as a third party service 2160 or other client device 2150, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

Further, in at least one embodiment, a cold plate includes adjustable fins forming microchannels for fluid to flow through. In at least one embodiment, fins in a cold plate enable transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processor-less system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processor-less system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

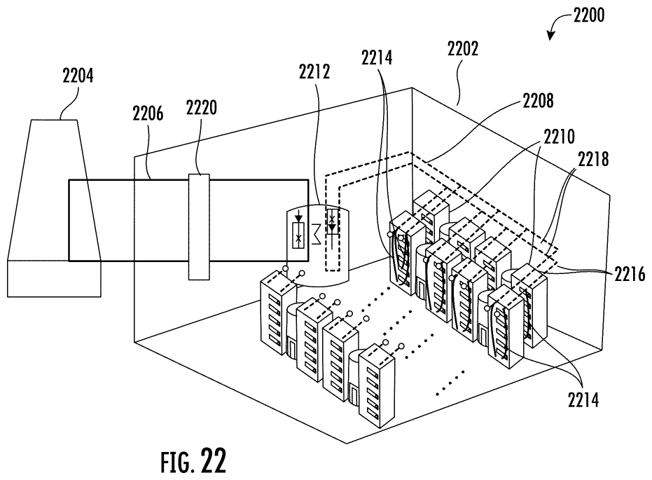

In at least one embodiment, an exemplary datacenter 2200 can be utilized as illustrated in FIG. 22, which has a cooling system subject to improvements described herein. In at least one embodiment, numerous specific details are set forth to provide a thorough understanding, but concepts herein may be practiced without one or more of these specific details. In at least one embodiment, datacenter cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a datacenter. In at least one embodiment, heat generated from these components, servers, and racks are cumulatively referred to as a heat feature or a cooling requirement as cooling requirement must address a heat feature entirely.

In at least one embodiment, a datacenter liquid cooling system is disclosed. In at least one embodiment, this datacenter cooling system addresses heat features in associated computing or datacenter devices, such as in graphics processing units (GPUs), in switches, in dual inline memory module (DIMMs), or central processing units (CPUs). In at least one embodiment, these components may be referred to herein as high heat density computing components. Furthermore, in at least one embodiment, an associated computing or datacenter device may be a processing card having one or more GPUs, switches, or CPUs thereon. In at least one embodiment, each of GPUs, switches, and CPUs may be a heat generating feature of a computing device. In at least one embodiment, a GPU, a CPU, DPU, QPU, PPU, or a switch may have one or more cores, and each core may be a heat generating feature.

In at least one embodiment, a cold plate includes adjustable fins forming microchannels for fluid to flow through. In at least one embodiment, fins in a cold plate enable transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least one embodiment, a cold plate has a top plate, a bottom plate, and fins in between In at least one embodiment, a bottom plate may be a base of a cold plate. In at least one embodiment, a top plate may be intermediary between a cover plate of a cold plate and a bottom or base plate of a cold plate. In at least one embodiment, fins may be coupled to a bottom or base plate and to a top plate so that a top plate may be moved to uncover an overlapping portion of each fin and expose an overlapping portion of each fin to fluid flowing through a cold plate. In at least one embodiment, exposure of an overlapping portion of each fin results in surface area previously covered to be exposed to fluid and to provide additional cooling of fins of a cold plate, and by association, of an associated computing device.

In at least one embodiment, multiple fins form microchannels for fluid to flow therebetween. In at least one embodiment, such fins are able to actively or passively react to thermal feedback by a modification of microchannels to enable fluid to absorb more heat from at least one computing device. In at least one embodiment, an active reaction may be enabled by at least one processor that can expose more surface area of such fins by expanding an overlapping portion of such fins. In at least one embodiment, a passive reaction may be enabled by a thermal property of materials associated together to form each fin of such fins that allows such fins to expand.

In at least one embodiment, issues of cold plates being static devices are addressed by intelligent and dynamic cold plates herein. In at least one embodiment, an intelligent and dynamic cold plate allows a cold plate (via its internal features) to react to sensed or determined temperature from at least one computing device. In at least one embodiment, compared to static cold plates, intelligence aspects of an intelligent and dynamic cold plate allow sensor inputs to be used to modify provided fins of such a cold plate. In at least one embodiment, microchannels formed by such fins are able to be changed to cause a change in a fluid path or to increase interaction surfaces between a fluid and each such fin. In at least one embodiment, such aspects allow more fluid to pass through to certain areas or to pass through certain areas and allow heat removal in those areas where high heat density occurs from at least one computing device.

In at least one embodiment, static cold plates used for liquid cooling of GPU, CPU, QPU, PPU, Switches, and other high heat density components may have static microchannels allowing flow of fluid therein to remove heat from such heat dissipating components in datacenters. In at least one embodiment, static cold plates incorporate design and methods for heat removal that are not related to or reactive to heat density or heat dissipation by computing components. In at least one embodiment, some cold plates may have varying thermal behaviors depending on computational, environmental and other attributes that require a dynamic behavior for achieving optimum heat removal capability for available resources in a liquid cooled environment.

In at least one embodiment, an indirect cooling cold plate, which is liquid-cooled, may be composed of parts therein. In at least one embodiment, two parts may be provided so that a bottom or base layer or part provides a rigid mechanical attachment and also works as a highly thermal conductive medium where heat is conducted from computing components (GPU, Switch, and CPU, DPU, QPU, PPU) to multiple fins forming microchannels over a bottom or base plate or part. In at least one embodiment, such fins are built into a base metal and may be associated with a top or upper plate or part, which is an intermediary plate or part. In at least one embodiment, a top or upper plate or part that is an intermediary plate or part is non-conductive and made of a non-conductive material. In at least one embodiment, a cover plate encloses (with side plates) such parts within an intelligent and dynamic cold plate.

In at least one embodiment, a top or upper plate or part, by its intermediary plate or part function, is able to dynamically modify a base plate's microchannel fluid path based in part on an instantaneous thermal behavior of heating components associated with an intelligent and dynamic cold plate. In at least one embodiment, using intelligent sensing, inferencing and adaptive modification, microchannels forming fluid paths may be dynamically adjusted to cause or rush more fluid (for heat removal) to areas of high heat density within an intelligent and dynamic cold plate. In at least one embodiment, such features also enable simultaneous reduction of fluids flow to block microchannels for areas where there is less demand for heat removal determined or sensed from a base plate of an intelligent and dynamic cold plate. In at least one embodiment, an overlapping portion of provided fins within an intelligent and dynamic cold plate may be used to block or restrict microchannels by being thicker at an overlapping portion between fins of an intelligent and dynamic cold plate. In at least one embodiment, multiple top plates may be provided to function as intermediary plates and may each be associated with different fins. In at least one embodiment, movement of different top plates achieve different blocks or restrictions or flow redirection within an intelligent and dynamic cold plate.

Datacenters and other networking systems may include connections between datacenters, switch systems, servers, racks, and devices in order to provide for signal transmission between one or more of these elements. These connections may be made using cables, transceivers, interconnects, interposers, and connector assemblies. For high bandwidth applications and/or connections over long distances, high powered optical communications may be preferred to ensure signal transmission integrity.

In at least one embodiment, an exemplary datacenter 2200 can be utilized as illustrated in FIG. 22, which has a cooling system subject to improvements described herein. In at least one embodiment, a datacenter 2200 may be one or more rooms 2202 having racks 2210 and auxiliary equipment to house one or more servers on one or more server trays. In at least one embodiment, a datacenter 2200 is supported by a cooling tower 2204 located external to a datacenter 2200. In at least one embodiment, a cooling tower 2204 dissipates heat from within a datacenter 2200 by acting on a primary cooling loop 2206. In at least one embodiment, a cooling distribution unit (CDU) 2212 is used between a primary cooling loop 2206 and a second or secondary cooling loop 2208 to enable absorption of heat from a second or secondary cooling loop 2208 to a primary cooling loop 2206. In at least one embodiment, a secondary cooling loop 2208 can access various plumbing into a server tray as required, in an aspect. In at least one embodiment, loops 2206, 2208 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 2206; 2208. In at least one embodiment, one or more coolant pumps may be used to maintain pressure differences within coolant loops 2206, 2208 to enable movement of coolant according to temperature sensors in various locations, including in a room, in one or more racks 2210, and/or in server boxes or server trays within one or more racks 2210.

In at least one embodiment, coolant in a primary cooling loop 2206 and in a secondary cooling loop 2208 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 2210. In at least one embodiment, a CDU 2212 is capable of sophisticated control of coolants, independently or concurrently, within provided coolant loops 2206, 2208. In at least one embodiment, a CDU may be adapted to control flow rate of coolant so that coolant is appropriately distributed to absorbed heat generated within associated racks 2210. In at least one embodiment, more flexible tubing 2214 is provided from a secondary cooling loop 2208 to enter each server tray to provide coolant to electrical and/or computing components therein.

In at least one embodiment, tubing 2218 that forms part of a secondary cooling loop 2208 may be referred to as room manifolds. Separately, in at least one embodiment, further tubing 2216 may extend from row manifold tubing 2218 and may also be part of a secondary cooling loop 2208 but may be referred to as row manifolds. In at least one embodiment, coolant tubing 2214 enters racks as part of a secondary cooling loop 2208 but may be referred to as rack cooling manifold within one or more racks. In at least one embodiment, row manifolds 2216 extend to all racks along a row in a datacenter 2200. In at least one embodiment, plumbing of a secondary cooling loop 2208, including coolant manifolds 2218, 2216, and 2214 may be improved by at least one embodiment herein. In at least one embodiment, a chiller 2220 may be provided in a primary cooling loop within datacenter 2202 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 2210 may be transferred to a coolant exiting one or more racks 2210 via flexible tubing of a row manifold 2214 of a second cooling loop 2208. In at least one embodiment, second coolant (in a secondary cooling loop 2208) from a CDU 2212, for cooling provided racks 2210, moves towards one or more racks 2210 via provided tubing. In at least one embodiment, second coolant from a CDU 2212 passes from on one side of a room manifold having tubing 2218, to one side of a rack 2210 via a row manifold 2216, and through one side of a server tray via different tubing 2214. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 2210 comes out of different side (such as exiting side) of tubing 2214 and moves to a parallel, but also exiting side of a row manifold 2216. In at least one embodiment, from a row manifold 2216, spent second coolant moves in a parallel portion of a room manifold 2218 and is going in an opposite direction than incoming second coolant (which may also be renewed second coolant), and towards a CDU 2212.

In at least one embodiment, spent second coolant exchanges its heat with a primary coolant in a primary cooling loop 2206 via a CDU 2212. In at least one embodiment, spent second coolant may be renewed (such as relatively cooled when compared to a temperature at a spent second coolant stage) and ready to be cycled back to through a second cooling loop 2208 to one or more computing components. In at least one embodiment, various flow and temperature control features in a CDU 2212 enable control of heat exchanged from spent second coolant or flow of second coolant in and out of a CDU 2212. In at least one embodiment, a CDU 2212 may be also able to control a flow of primary coolant in primary cooling loop 2206.

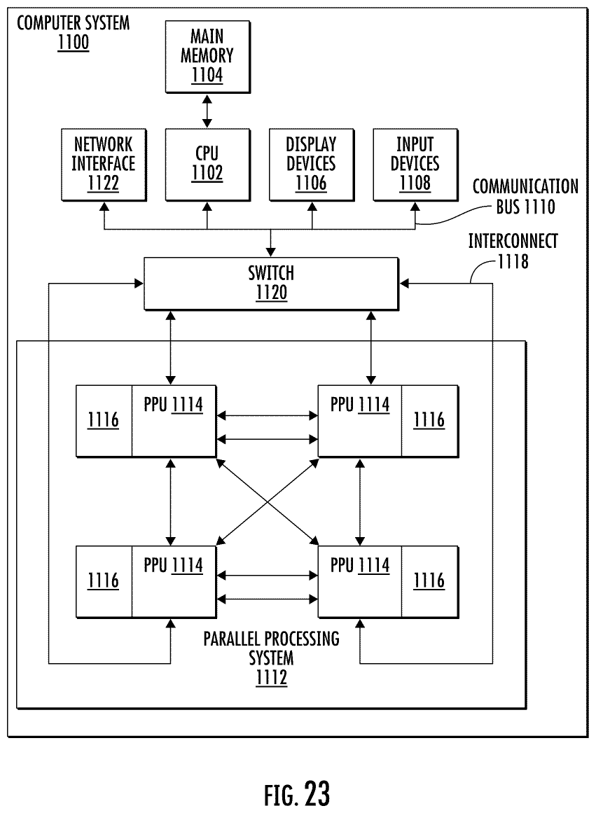

FIG. 23 illustrates a computer system 1100, according to at least one embodiment. In at least one embodiment, computer system 1100 is configured to implement various processes and methods described throughout this disclosure.

In at least one embodiment, computer system 1100 comprises, without limitation, at least one central processing unit (“CPU”) 1102 that is connected to a communication bus 1110 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1100 includes, without limitation, a main memory 1104 and control logic (e.g., implemented as hardware, software, or a combination thereof) and data are stored in main memory 1104 which may take form of random access memory (“RAM”). In at least one embodiment, a network interface subsystem (“network interface”) 1122 provides an interface to other computing devices and networks for receiving data from and transmitting data to other systems from computer system 1100.

In at least one embodiment, computer system 1100, in at least one embodiment, includes, without limitation, input devices 1108, parallel processing system 1112, and display devices 1106 which can be implemented using a conventional cathode ray tube (“CRT”), liquid crystal display (“LCD”), light emitting diode (“LED”), plasma display, or other suitable display technologies. In at least one embodiment, user input is received from input devices 1108 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1104 and/or secondary storage. Computer programs, if executed by one or more processors, enable system 1100 to perform various functions in accordance with at least one embodiment. memory 1104, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1102; parallel processing system 1112; an integrated circuit capable of at least a portion of capabilities of both CPU 1102; parallel processing system 1112; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1100 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1112 includes, without limitation, a plurality of parallel processing units (“PPUs”) 1114 and associated memories 1116. In at least one embodiment, PPUs 1114 are connected to a host processor or other peripheral devices via an interconnect 1118 and a switch 1120 or multiplexer. In at least one embodiment, parallel processing system 1112 distributes computational tasks across PPUs 1114 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1114, although such shared memory may incur performance penalties relative to use of local memory and registers resident to a PPU 1114. In at least one embodiment, operation of PPUs 1114 is synchronized through use of a command such as_syncthreads( ), wherein all threads in a block (e.g., executed across multiple PPUs 1114) to reach a certain point of execution of code before proceeding.

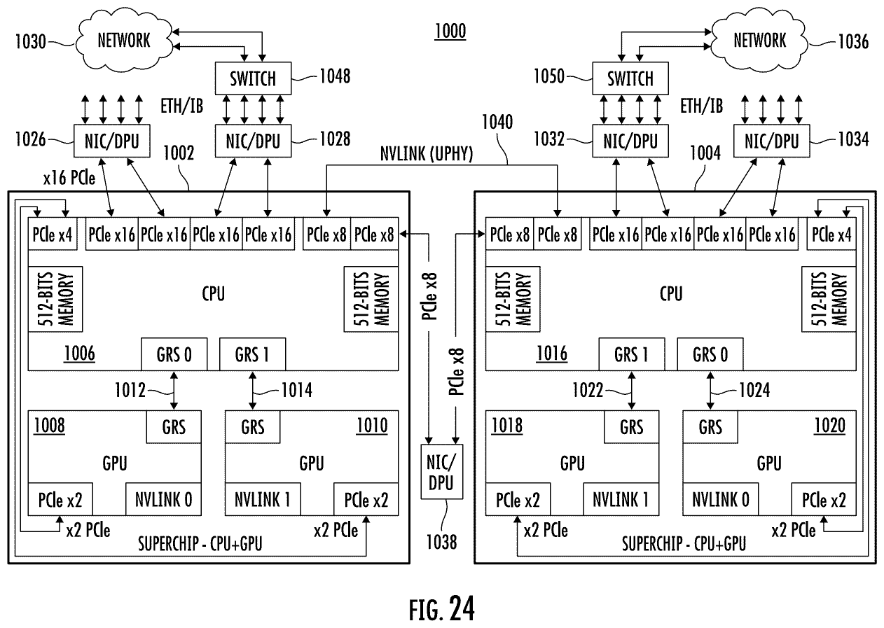

FIG. 24 is a block diagram that schematically illustrates a computing system 1000, e.g., a data center or a High-Performance Computing (HPC) cluster, in accordance with an embodiment that is described herein. System 1000 comprises a plurality of subsystems, e.g. multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 24 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 24, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 24, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communication with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 24 may comprise, for example, Nvidia Quantum-2 switches. The NICs/DPUs in the figure may comprise, for example, Nvidia Bluefield DPUs.

Many modifications and other embodiments of the present disclosure set forth herein will come to mind to one skilled in the art to which these embodiments pertain having the benefit of the teachings presented in the foregoing descriptions and the associated drawings. Although the figures only show certain components of the systems, apparatuses, and methods described herein, it is understood that various other components may also be included. In addition, the methods described above may include fewer steps in some cases, while in other cases may include additional steps. The steps and modifications to the steps of the method described above, in some cases, may be performed in any order and in any combination.

Therefore, it is to be understood that the disclosure is not to be limited to the specific embodiments disclosed herein and that modifications and other embodiments are intended to be included within the scope of the appended claims. Although specific terms are employed herein, they are used in a generic and descriptive sense only and not for purposes of limitation.

1. A system comprising:
a distribution manifold defining:
a plurality of entrance flow passages configured to receive a heat transfer fluid therethrough, and
a plurality of exit flow passages configured to receive the heat transfer fluid therethrough; and
a heat transfer plate comprising a plurality of heat transfer surfaces disposed proximate the distribution manifold, wherein the plurality of heat transfer surfaces extends from the heat transfer plate toward the distribution manifold, and wherein the plurality of heat transfer surfaces defines a plurality of gaps therebetween,
wherein the plurality of entrance flow passages is configured to deliver the heat transfer fluid to the plurality of gaps, and
wherein the plurality of exit flow passages is configured to receive the heat transfer fluid from the plurality of gaps.

2. The system of claim 1 further comprising a gasket configured to be disposed proximate the distribution manifold.

3. The system of claim 2, wherein the gasket is configured to form a seal between the entrance flow passages and the exit flow passages to prevent a bypass of the heat transfer fluid, and wherein the gasket is further configured to:
control an inflow of the heat transfer fluid to the entrance flow passages; and
control an outflow of the heat transfer fluid from the exit flow passages.

4. The system of claim 3, wherein the gasket further defines:
an entrance aperture, wherein the entrance aperture is configured to distribute the heat transfer fluid to the entrance flow passages, and
an exit aperture, wherein the exit aperture is configured to receive the heat transfer fluid from the exit flow passages.

5. The system of claim 4, wherein the gasket further defines at least two exit apertures, wherein each exit aperture is configured to be aligned with an end of a respective exit flow passage.

6. The system of claim 2 wherein the gasket is configured to distribute the heat transfer fluid to the plurality of gaps; and
wherein the gasket is configured to receive the heat transfer fluid from the plurality of gaps.

7. The system of claim 6, wherein the gasket is configured to form a seal between each of the plurality of heat transfer surfaces to prevent a bypass of the heat transfer fluid, and wherein the gasket is further configured to:
control an inflow of the heat transfer fluid to the plurality of gaps; and
control an outflow of the heat transfer fluid from the plurality of gaps.

8. The system of claim 1 further comprising a coupler in fluid communication with the plurality of entrance flow passages, wherein the coupler is configured to receive the heat transfer fluid from a source of heat transfer fluid, and wherein the coupler is configured to deliver the heat transfer fluid to the plurality of entrance flow passages.

9. The system of claim 8 further comprising:
a top cover configured to be disposed proximate a gasket; and
the coupler in fluid communication with the top cover and configured to receive the heat transfer fluid from a source of heat transfer fluid, and wherein the coupler is configured to deliver the heat transfer fluid to the top cover,
wherein the top cover further defines an entrance opening, wherein the entrance opening is configured to promote even distribution of the heat transfer fluid to an entrance aperture of the gasket, and
wherein the top cover further defines an exit opening, wherein the exit opening is configured to receive the heat transfer fluid from an exit aperture of the gasket.

10. The system of claim 9, wherein the coupler is further configured to receive the heat transfer fluid from the plurality of exit flow passages.

11. The system of claim 1, wherein the system is configured to promote temperature regulation of a component comprising at least one of:
a graphics processing unit;
a data processing unit;
a central processing unit; or
an electronic device.

12. A distribution manifold comprising:
a plurality of entrance flow passages configured to receive a heat transfer fluid therethrough, and
a plurality of exit flow passages configured to receive the heat transfer fluid therethrough;
wherein the distribution manifold is configured to be disposed proximate a heat transfer plate comprising a plurality of heat transfer surfaces, wherein the plurality of heat transfer surfaces extends from the heat transfer plate toward the distribution manifold, and wherein the plurality of heat transfer surfaces defines a plurality of gaps therebetween,
wherein the plurality of entrance flow passages is configured to deliver the heat transfer fluid to the plurality of gaps, and
wherein the plurality of exit flow passages is configured to receive the heat transfer fluid from the plurality of gaps.

13. The distribution manifold of claim 12, wherein the distribution manifold defines a first end and a second end, wherein at least one of the plurality of entrance flow passages is narrower proximate the first end and is wider proximate the second end.

14. The distribution manifold of claim 12, wherein the distribution manifold defines a first end and a second end, wherein at least one of the plurality of exit flow passages is wider proximate the first end and is narrower proximate the second end.

15. The distribution manifold of claim 12, wherein each of the plurality of entrance flow passages and each of the plurality of exit flow passages comprises at least one vertical flow channel, and wherein the plurality of entrance flow passages and the plurality of exit flow passages are in fluid communication with the plurality of gaps via the vertical flow channels.

16. The distribution manifold of claim 15, wherein at least one of the vertical flow channels defines a variable nominal width.

17. The distribution manifold of claim 16, wherein a nominal width of at least one of the vertical flow channels is determined based on an expected thermal performance of a component to be temperature-regulated proximate the at least one vertical flow channel.

18. The distribution manifold of claim 15, wherein at least one of the vertical flow channels further comprises a taper, wherein a direction of the taper corresponds to a direction of flow of the heat transfer fluid through the respective vertical flow channel.

19. The distribution manifold of claim 15, wherein each of the plurality of entrance flow passages and each of the plurality of exit flow passages defines a passage length, wherein a length of at least one of the vertical flow channels is substantially the same as the passage length.

20. The distribution manifold of claim 12, wherein the distribution manifold defines:
a transverse direction, wherein the plurality of entrance flow passages and the plurality of exit flow passages are aligned with the transverse direction; and
a longitudinal direction, wherein the gaps defined by the plurality of heat transfer surfaces are aligned with the longitudinal direction.

21. The distribution manifold of claim 12, wherein each of the plurality of entrance flow passages is substantially parallel to an adjacent exit flow passage.
